(19) United States
(12) Patent Application Publication
(10) Pub. No.: US 2008/0303022 A1
(43) Pub. Date: Dec. 11, 2008

(54) Optical sensor element, optical sensor device and image display device using optical sensor element

(75) Inventors: Mitsuharu Tai, Kokubunji (JP); Masayoshi Kinoshita, Hachioji (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 12/071,704

(22) Filed: Feb. 25, 2008

(30) Foreign Application Priority Data
Jun. 11, 2007 (JP) JP 2007-153490

(51) Int. Cl. H01L 31/0376

(52) U.S. Cl. 257/53; 257/E31.048

(57) ABSTRACT

A highly sensitive optical sensor element, and a switch element such as a sensor driver circuit are formed on the same insulating substrate by using an LTPS planar process to provide a low cost area sensor (optical sensor device) incorporating the sensor driver circuit and the like or an image display device incorporating the optical sensor element. As an optical sensor element structure, one electrode of the sensor element is manufactured with the same film of the polycrystalline silicon film that is an active layer of the switch element constituting a circuit. A photoelectric conversion unit for performing photoelectric conversion is made of an amorphous silicon or a polycrystalline silicon film of an intrinsic layer. A structure in which the amorphous silicon of the photoelectric conversion unit and the insulating layer are sandwiched between two electrodes of the sensor element is adopted.

### CROSS-REFERENCE TO RELATED APPLICATION

The present application claims priority from Japanese Patent Application No. JP 2007-153490 filed on Jun. 11, 2007, the content of which is hereby incorporated by reference into this application.

### TECHNICAL FIELD OF THE INVENTION

The present invention relates to thin-film optical sensor elements formed on insulation film substrates and optical sensor devices using the same, in particular, to optical sensor arrays such as X-ray imaging devices and near-infrared detection devices for biometric authentication. Also, the present invention relates to low temperature process light transmission elements, low temperature process photoconductor elements, or low temperature optical diode elements used in display devices with a display panel, such as liquid crystal displays, organic EL (Electro Luminescence) displays, inorganic EL displays, and EC (Electro Chromic) displays, having a touch panel function, a light adjustment function, and an input function using the optical sensor.

### BACKGROUND OF THE INVENTION

The X-ray imaging device is essential as a medical device, and therefore problems about easy operation of the device, and cost reduction in the device are always required. Recently, finger vein patterns and palm vein patterns biometric authentication have attracted attention as one means of biometric authentication, and the development of the devices for reading such information is urgent. In such devices, a sensor array occupying a certain area, a so-called area sensor, is necessary for outside-light detection for reading information, and thus the provision of the area sensor at low cost is required. Due to such requirement, a method of forming the area sensor on an inexpensive insulating substrate as represented by a glass substrate in a semiconductor forming process (planar process) has been proposed in Technology and Applications of Amorphous Silicon pp. 204-221 (Non-patent Document 1).

In other products field for area sensors, middle or small sized displays require optical sensors. The middle or small sized display is used in a display application for mobile equipment such as cellular phones, digital still cameras, and PDAs, and used in in-vehicle displays. Multifunction and higher performance are required for the displays. The optical sensor has attracted attention as an effective means for adding a light adjustment function as described in SHARP Technical Journal vol. 92 (2005) pp. 35-39 (Non-patent Document 2) and a touch panel function to the display. However, in the middle or small sized display, since the panel cost is low as compared to large displays, the rise in cost due to mounting of the optical sensors and the sensor drivers becomes large. Therefore, a technique in which the optical sensor elements and the sensor drivers are simultaneously formed in order to suppress increase in cost when pixel circuits are formed on a glass substrate by using the semiconductor process (planar process) has been considered as it is an effective technique.

The problem arising in a group of the products described above is that the optical sensor element and the sensor driver must be formed on an inexpensive insulating substrate. The sensor driver is normally configured by a LSI, and required to be a MOS transistor formed on a monocrystalline silicon wafer, or to be a high performance switch element similar to the MOS transistor. The following techniques are effective in order to form a high performance switch element on an inexpensive insulating substrate.

A thin-film transistor (hereinafter referred to as “polycrystalline silicon TFT”) in which a channel is composed of polycrystalline silicon is developed as a pixel and a pixel driving circuit element for active matrix type liquid crystal displays, and organic EL displays, and image sensors. The polycrystalline silicon TFT has an advantage in which its driving ability is larger as compared to other drive circuit elements, and has peripheral drive circuits mounted on the same glass substrate on which the pixels are formed. Thus, it is expected that the reduction in cost by simultaneously progressing customization of circuit specification, pixel design and a formation process, and higher reliability by avoiding mechanical vulnerability of the connections between the drive LSI and the pixels can be achieved.

The polycrystalline silicon TFT is formed on a glass substrate in terms of cost. In the process of forming the TFT on the glass substrate, the resistance-temperature of glass defines the process temperature. As a method of forming a high quality polycrystalline silicon thin-film without thermally damaging the glass substrate, there is a method (ELA method: Excimer Laser Anneal) in which a precursor silicon layer is melt and then recrystallized with excimer laser. In the polycrystalline silicon TFT obtained in this formation method, the driving ability is improved a hundred times or more as compared to a TFT (its channel is composed of amorphous silicon) used in conventional liquid crystal displays, and thus some circuits such as a driver can be mounted on a glass substrate.

The characteristics required for the optical sensor element are high output characteristics and low leakage characteristics at the time of dark. The high output characteristics mean that output as large as possible can be obtained with respect to certain light intensity, and so materials and element structures having high photocurrent conversion efficiency are required. The low leakage characteristics at the time of dark mean that output is as small as possible when light incidence dose not occur (small dark current).

FIG. 1A is a cross-sectional view of a conventional optical sensor element. FIG. 1A shows a PIN type diode element of a longitudinal structure type in which an amorphous silicon film serves as a photoelectric conversion layer. Here, in FIGS. 1A and 1B, the reference numeral “201” denotes an insulating substrate; “202” a first metal electrode; “203” an amorphous silicon layer; “203a” an intrinsic amorphous silicon layer; “203b” an N type amorphous silicon layer; “203c” P type amorphous silicon layer; “205” a second metal electrode; “208” an insulating layer for passivation; and “209” an insulating layer for isolating conductive layer.

The optical sensor element shown in FIG. 1A includes a photoelectric conversion layer of the intrinsic amorphous silicon layer 203a between a first metal electrode layer and a second metal electrode layer, and impurity implanted layers (N type amorphous silicon layer 203b and P type amorphous silicon layer 203c) formed between the photoelectric conversion layer and each electrode layer. The optical sensor element is formed on the insulating substrate 201. FIG. 1B shows a cross section in a vertical direction of the optical sensor element shown in FIG. 1A and an energy band diagram taken along the cross sectional direction at the time of a sensor operation. When a potential of the first electrode 202 is set higher than that of the second electrode 205, electron-hole pairs are induced by incident light in the intrinsic layer, and electrons are drifted to the second electrode 205 and holes are drifted to the first electrode 202. As a result, a current is generated from the second electrode 205 to the first electrode 202 in the sensor element. Since entering of the electrons from the first electrode 202 to the intrinsic layer and entering of the holes from the second electrode 205 to the intrinsic layer are prevented by potential barriers formed therebetween, amount of generated currents is proportional to incident light intensity. Therefore, the optical detection sensor can be realized by outputting the generated currents as the output.

Amorphous silicon has a large absorption coefficient over the entire wavelength region and a large photoelectric conversion rate. However, entering of charges from the electrodes can not be completely prevented by the potential barriers. In addition, since other generated currents which are not generated by incident light also exist, the amount of leakage current at the time of dark is relatively large in the structure of FIG. 1A.

FIG. 2A is an optical sensor element of a generated charge storage type disclosed in Japanese Patent Laid-Open Publication No. 8-116044 (Patent Document 1). The sensor element has a structure in which an amorphous silicon film 303 is a photoelectric conversion layer, and an insulation film 304 is interposed between the photoelectric conversion layer and one of the electrodes.

FIG. 2B to FIG. 2E show cross sections in the vertical direction of the optical sensor element shown in FIG. 2A and energy band diagrams taken along the cross sectional direction at the time of the sensor operation, and a timing chart diagram of the sensor operation. Here, in FIG. 2A to FIG. 2D, the numeral reference “301” denotes an insulating substrate; “302” a first metal electrode; “303” an amorphous silicon film; “303a” an intrinsic amorphous silicon film; “303b” an N type amorphous silicon film; “304” an insulating film; “305” a second metal electrode; “308” an insulating layer for passivation; and “309” an insulating layer for isolating conductive layers.

In a reset/read-out mode, the potential of the first metal electrode 302 is retained higher to the second metal electrode 305 to discharge the holes existing in the amorphous silicon film 303 to a side of the second metal electrode 305. In a sensor operation mode, the potential of the first metal electrode 302 is retained lower to the second metal electrode 305 to discharge the remaining electrons and the electrons induced by the incident light in the amorphous silicon film 303, and simultaneously to store the holes induced by incident in the amorphous silicon film 303 on a side of the first metal electrode 302. In the subsequent reset/read-out mode, the stored holes are read out as charges. The total amount of charges is proportional to the amount of incident light in one time of the sensor operation mode.

In optical sensor element of the generated charge storage type, a voltage must be sequentially changed as described above, so that the sensor operating method is complicated. However, the amount of leakage current at the time of dark is small since the insulation film is interposed. In addition, since the sequence of the timing of the sensor operation can be freely set, optimum adjustment of the sensor output can be conducted by external inputs after forming the element. A gray scale read-out is also possible depending on the setting. Thus, the SN ratio is higher and a degree of freedom of operation is larger as compared to the sensor shown in FIG. 1(A).

When an amorphous silicon film is applied to switch elements constituting circuits and the like, since a performance of the switch elements is insufficient, it is impossible to constitute a driver circuit. For example, when TFT is composed of an amorphous silicon film, its field-effect mobility is lower than or equal to 1 cm²/Vs. Thus, a sensor has a configuration in which the elements having the structure shown in FIG. 2 are arrayed, whereby a discrete driver LSI as a switch function is mounted and connected with FPC or the like. In this case, the cost is high, and the number of connecting points between the drive LSI and the panel is large, and therefore, the mechanical strength cannot be sufficiently ensured.

Japanese Patent Laid-Open Publication No. 2004-159273 (Patent Document 2), Japanese Patent Laid-Open Publication No. 2004-325961 (Patent Document 3), Japanese Patent Laid-Open Publication No. 2004-318819 (Patent Document 4), and Japanese Patent Laid-Open Publication No. 2006-3857 (Patent document 5) each disclose a structure in which active layers of the switch elements and the photoelectric conversion layers of the sensor elements are composed of polycrystalline silicon; and the optical sensor elements and the sensor drivers are formed on the inexpensive insulating substrates. According to the methods, the reduction in cost by simultaneously progressing customization of a circuit specification, designs and formation steps of the pixels and sensors, and the reduction in the number of connecting points between the drive LSI and the panel can be realized. However, in this case, sufficient sensor output is not obtained. The reason for this is that the polycrystalline silicon layer cannot be made thick for ensuring the switch characteristics, and the polycrystalline silicon film has a small absorption coefficient as compared to an amorphous silicon film, whereby most of light is not absorbed by the film and is transmitted therethrough.

A biometric authentication device includes a sensor array part in which sensors are arranged in a matrix shape. The sensor array part has a function of acquiring biometric information as image signals, and is generally configured by CMOS sensors or CCD cameras. Since the CMOS sensor and CCD camera are small as compared to the reading area, a reduction optical system or the like is added to the photoelectric conversion surface side, so that the structure is a large in thickness. In recent years, applications of them for security measures of a personal computer login, ATM, and room entering/leaving management are considered, and therefore, thinning of the device and reduction in cost of the device are desired.

With sensor elements arranged on an insulating substrate, an area of a sensor array can be enlarged at low cost, and thus the reduction optical system is not required, and therefore, there is a possibility of providing a device that meets with an object as described above. In the sensor elements disclosed in Patent Documents 2 to 5, these elements cannot detect near-infrared light used in a biometric authentication device or the like due to absorption characteristics of the photoelectric conversion part. Therefore, it is difficult to constitute a biometric authentication device. In the conventional sensor element shown in FIG. 2A, the amount of leakage current at the time of dark is small, and the near-infrared light can be detected, but since the signal strength is very small, an amplification circuit is required. In the case where the amplification circuit configured with a LSI is mounted outside the sensor array part, the authentication devices become large and expensive due to the mounting area and the cost of the LSI.

Japanese Patent Laid-Open Publication No. 2005-228895 (Patent Document 6) discloses a structure in which: the switch element is composed of a polycrystalline silicon film; circuits such as drivers are formed; and then a sensor element having a photoelectric conversion layer composed of an amorphous silicon film is formed on upper layers of the switch element and circuits. If the sensor element described in Patent Document 6 is used, the optical sensor element and the sensor drive are formed on the inexpensive insulating substrate. Accordingly, the thinner and lower-cost biometric authentication devices as compared to the conventional products, the low cost and high sensitive area sensors with the built-in sensor driver, or the image display devices with the built-in optical sensor element can be provided. However, this structure has a process in which a sensor element formation process has to include a circuit formation step. In the case of forming such a multi-layered structure, since it is difficult to ensure flatness of the elements, the sensor characteristics are difficult to ensure due to variation in optical characteristics. Furthermore, it is concerned that yield deteriorates due to many manufacturing steps.

### SUMMARY OF THE INVENTION

An object of the present invention is to provide low-cost and highly sensitive area sensors incorporating a sensor driver circuit and image display devices incorporating an optical sensor element, wherein the optical sensor element having high photoelectric conversion efficiency, and the sensor driver circuit (pixel circuit or other circuits as necessary) are formed on the same insulation film substrate by using a planar process.

As a measure for solving the problems, the present invention provides an optical sensor element, which is formed on an insulating substrate, comprising a first electrode, a second electrode, a photoelectric conversion layer composed of a semiconductor layer between the first electrode and the second electrode, and an insulating layer between the first electrode and the second electrode, wherein the first electrode is composed of a polycrystalline silicon film.

The present invention provides an optical sensor device comprising an optical sensor element formed on an insulating substrate, wherein the optical sensor element includes: a first electrode composed of a polycrystalline silicon film; a second electrode; a photoelectric conversion layer composed of a semiconductor layer between the first electrode and the second electrode; and an insulating layer between the first electrode and the second electrode, and elements of at least one type selected from a thin-film transistor device, a diode element, and a resistor element, wherein the thin-film transistor device, the diode element, and the resistor element have an active layer composed of the same film of the polycrystalline silicon film forming the first electrode of the optical sensor element, and wherein an amplification circuit and a sensor driver circuit constituted by the elements of at least one type selected from the thin-film transistor device, the diode element, and the resistor element are manufactured on the same insulating substrate together with the optical sensor element.

Also, the present invention provides an image display device comprising an optical sensor element formed on an insulating substrate, wherein the optical sensor element includes: a first electrode composed of a polycrystalline silicon film; a second electrode; a photoelectric conversion layer composed of a semiconductor layer between the first electrode and the second electrode; and an insulating layer between the first electrode and the second electrode, and elements of at least one type selected from a thin-film transistor device, a diode element, and a resistor element, and wherein the thin-film transistor device, the diode element, the and resistor element have an active layer composed of the same film of the polycrystalline silicon film forming the first electrode of the optical sensor element, and wherein an optical sensor device is configured by an amplification circuit and an sensor driver circuit that are constituted by the elements of at least one type selected from the thin-film transistor device, the diode element, and the resistor element, and that are manufactured on the same insulating substrate together with the optical sensor element, and wherein a pixel switch, an amplification circuit and a pixel driver circuit constituted by the elements of at least one type selected from the thin-film transistor device, the diode element, and the resistor element are manufactured on the same insulating substrate.

According to the present invention, an amplification circuit, and a switch element constituting a sensor driver are manufactured, and simultaneously a highly performance optical sensor element of the generated charge storage type is manufactured. The element structure is characterized by that one electrode of the sensor element is the same film of the polycrystalline silicon film forming an active layer of the switch element, a photoelectric conversion unit for performing photoelectric conversion is made of amorphous silicon, and the amorphous silicon of the photoelectric conversion unit and an insulating layer are sandwiched between two electrodes of the sensor element. Thus, while increase in the number of process steps is suppressed as much as possible, the switching characteristics of the sensor driver circuit is ensured, and an optical sensor device that has the highly sensitive and low noise optical element composed of the amorphous silicon film and an image display device using the optical sensor device are realized.

(Note 1) One of the features of the present invention is an optical sensor formed on an insulating substrate and comprising: a first electrode; a second electrode; a photoelectric conversion layer composed of a semiconductor layer between the first electrode and the second electrode; and a insulating film between the first electrode and the second electrode, wherein the first electrode is composed of a polycrystalline silicon film. This is to prevent the leakage current at the time of dark by the insulating film.

(Note 2) According to Note 1, it is desirable that the photoelectric conversion layer composed of an amorphous silicon film is formed on an upper part of the first electrode, the insulating layer is formed on an upper part of the photoelectric conversion layer, and the second electrode is further formed on an upper part of the insulating layer. This is to prevent leakage current at the time of dark by the insulating film.

(Note 3) According to Note 2, it is desirable that the first electrode has a resistivity of 2.5×10⁻⁴ Ω·m or less, and the photoelectric conversion layer has a resistivity of 1.0×10⁻³ Ω·m or larger. The reason for this is that the first electrode must be a conductor to extend the lifespan of the generated electron-hole pairs.

(Note 4) According to Note 2, it is desirable that the second electrode has a transmittance of 75% or larger with respect to a light of a visible near-infrared light region of 400 nm to 1000 nm.

(Note 5) According to Note 2, it is desirable that a region adjacent to an interface with the first electrode in the amorphous silicon film forming the photoelectric conversion layer is an impurity implanted region with higher concentration of 1×10²⁵/m³ or higher. This is because the carriers must be prevented from entering the photoelectric conversion layer from the electrode.

(Note 6) According to Note 5, it is desirable that an impurity element with the same kind as that of an impurity element in the impurity implanted region with higher concentration is present in the first electrode, and the impurity is at least one selected from phosphorus, arsenic, boron, and aluminum. Introducing the same type impurity can reduce the leakage when the irradiation of light does not occur.

(Note 7) According to Note 2, it is desirable that the insulating layer is composed of a silicon oxide layer or a silicon nitride layer

(Note 8) According to Note 1, it is desirable that the insulating layer is formed on an upper part of the first electrode, the photoelectric conversion layer composed of an amorphous silicon film is formed on an upper part of the insulating layer, and the second electrode is further formed on an upper part of the photoelectric conversion layer. This is to prevent leakage current at the time of dark by the insulating film.

(Note 9) According to Note 8, it is desirable that the first electrode has a resistivity of 2.5×10⁻⁴ Ω·m or smaller, and the photoelectric conversion layer has a resistivity of 1.0×10⁻³ Ω·m or larger. The reason for this is that the first electrode must be a conductor to extend the lifespan of the generated electron-hole pairs.

(Note 10) According to Note 8, it is desirable that the second electrode has a transmittance of 75% or larger with respect to light of a visible near-infrared light region of 400 nm to 1000 nm.

(Note 11) According to Note 8, it is desirable that a region adjacent to an interface with the second electrode of in the amorphous silicon film forming the photoelectric conversion layer is an impurity implanted region with higher concentration of 1×10²⁵/m³ or higher. This is because the carriers must be prevented from entering the photoelectric conversion layer from the electrode.

(Note 12) According to Note 11, it is desirable that an impurity element different in kind from an impurity element in the impurity implanted region with higher concentration is present in the first electrode, and is at least one selected from phosphor, arsenic, boron, and aluminum. Introducing the different type impurity can reduce the leakage when the irradiation of light does not occur.

(Note 13) According to Note 8, it is desirable that the insulating layer is composed of a silicon oxide layer or a silicon nitride layer.

(Note 14) According to Note 1, it is desirable that the first electrode; the photoelectric conversion layer adjacent to the first electrode and composed of the same film of the polycrystalline silicon film forming the first electrode; the insulating layer formed on an upper part of the photoelectric conversion layer; and the second electrode formed on an upper part of the insulating layer are formed. This is to prevent leakage current at the time of dark by the insulating film.

(Note 15) According to Note 14, it is desirable that the first electrode has a resistivity of 2.5×10⁻⁴ Ω·m or smaller, and the photoelectric conversion layer has a resistivity of 1.0×10⁻³ Ω·m or larger. The first electrode must be a conductor because the lifespan of the electron-hole pairs generated by making the photoelectric conversion layer as an intrinsic layer of a polycrystalline silicon film must be extended.

(Note 16) According to Note 14, it is desirable that the second electrode has a transmittance of 75% or larger with respect to light of a visible near-infrared light region of 400 nm to 1000 nm.

(Note 17) According to Note 14, it is desirable that the insulating layer is composed of a silicon oxide layer or a silicon nitride layer.

(Note 18) One of the features of the present invention is also an optical sensor device comprising: an optical sensor element formed on an insulating substrate, wherein the optical sensor element includes a first electrode composed of a polycrystalline silicon film, a second electrode, a photoelectric conversion layer composed of a semiconductor layer formed between the first electrode and the second electrode, and an insulating layer formed between the first electrode and the second electrode; and at least one of a thin-film transistor device, a diode element, and a resistor element, each of which is composed of the same film of the polycrystalline silicon film forming the first electrode of the optical sensor element and which configure active layer, wherein an amplification circuit and a sensor driver circuit constituted by at least one of the thin-film transistor device, the diode element, and the resistor element are manufactured on the same insulating substrate together with the optical sensor element. This is to make an optical sensor device having the optical element formed with the amorphous silicon film, with high sensitivity and low noise characteristics, while suppressing increase in the number of steps as much as possible and maintaining the switching characteristics of the sensor driver circuit.

(Note 19) According to Note 18, it is desirable that sets of the optical sensor or the optical sensor element and amplification circuit thereof, and a switch group are arranged in a matrix shape, and the sensor driver circuit is disposed around the matrix.

(Note 20) One of the features of the present invention is also an image display device comprising: an optical sensor device including an optical sensor element formed over an insultating film, wherein the optical sensor element includes a first electrode composed of a polycrystalline silicon film, a second electrode, a photoelectric conversion layer composed of a semiconductor layer formed between the first electrode and the second electrode, and an insulating layer formed between the first electrode and the second electrode; and at least one of a thin-film transistor device, a diode element, and a resistor element, each of which is composed of the same film of the polycrystalline silicon film forming the first electrode of the optical sensor element and which configure an active layer, wherein an amplification circuit and a sensor driver circuit constituted by at least one of the thin-film transistor device, the diode element, and the resistor element are manufactured on the same insulating substrate together with the optical sensor element, and wherein a pixel switch, an amplification circuit and a pixel driver circuit, each of which is constituted by at least one of the thin-film transistor device, the diode element, and the resistor element, are manufactured on the same insulating substrate. This is to make an image display device including the optical sensor device with the optical element formed with the amorphous silicon film, with high sensitivity and low noise characteristics, while suppressing increase in the number of steps as much as possible and maintaining the switching characteristics of the sensor driver circuit.

(Note 21) According to Note 20, it is desirable that sets of one pixel or a plurality of pixels, the optical sensor element or the optical sensor and amplification circuit thereof, and a switch group are arranged in a matrix shape, and the pixel driver circuit and the sensor driver circuit are disposed around the matrix.

(Note 22) According to Note 20, it is desirable that the pixels are arranged in a matrix shape, and the optical sensor element, the pixel driver circuit, and the sensor driver circuit are arranged at the periphery of the matrix.

In order to realize a high added-value for the conventional TFT driven display, the addition of functions is essential. As a measure for this, incorporating optical sensors is very effective because it expands applicable functions that can be added. The area sensor in which the optical sensors are arrayed is effective in medical applications and authentication applications, and thus it becomes important to be manufactured at low cost.

According to the present invention, a high performance sensor and a sensor processing circuit can be simultaneously manufactured on an inexpensive insulating substrate to provide low cost and highly reliable products.

### BRIEF DESCRIPTIONS OF THE DRAWINGS

FIG. 1A is a schematic cross-sectional view for describing an conventional optical sensor element;

FIG. 1B is an energy band diagram for describing the conventional optical sensor element;

FIG. 2A is a schematic cross-sectional view for describing an optical sensor element of a generated charge storage type disclosed in patent document 1;

FIG. 2B is an energy band diagram of the optical sensor element of a generated charge storage type disclosed in patent document 1;

FIG. 2C is an energy band diagram of the optical sensor element of a generated charge storage type disclosed in patent document 1;

FIG. 2D is an energy band diagram of the optical sensor element of a generated charge storage type disclosed in patent document 1;

FIG. 2E is a timing chart at the time of sensor operation for the optical sensor element of a generated charge storage type disclosed in patent document 1;

FIG. 3A is a cross-sectional view showing a conceptual view for describing an embodiment of an optical sensor element of according to the present invention;

FIG. 3B is a top view showing a conceptual view for describing the embodiment of the optical sensor element according to the present invention;

FIG. 4A is a cross-sectional view showing a conceptual view for describing another embodiment of an optical sensor element according to the present invention;

FIG. 4B is a top view showing a conceptual view for describing another example of the optical sensor element according to the present invention;

FIG. 5A is a cross-sectional view showing a conceptual view of a thin-film transistor (TFT) widely used as a switch element using a polycrystalline silicon film;

FIG. 5B is a top view showing a conceptual view of the thin-film transistor (TFT) widely used as a switch element using a polycrystalline silicon film;

FIG. 6 is a cross-sectional view showing introduction of impurities, which is the same type as the impurity type implanted into the first electrode, into the region adjacent to the first electrode in the sensor element shown in FIG. 3;

FIG. 7 is a cross-sectional view showing an introduction of impurities, which is a different type with respect to the impurity type implanted into the first electrode, into the region adjacent to the second electrode in the sensor element shown in FIG. 4;

FIG. 8A is a process diagram describing process of manufacturing the optical sensor element and the polycrystalline silicon TFT;

FIG. 8B is a process diagram describing process of manufacturing the optical sensor element and the polycrystalline silicon TFT;

FIG. 8C is a process diagram describing process of manufacturing the optical sensor element and the polycrystalline silicon TFT;

FIG. 8D is a process diagram describing process of manufacturing the optical sensor element and the polycrystalline silicon TFT;

FIG. 8E is a process diagram describing process of manufacturing the optical sensor element and the polycrystalline silicon TFT;

FIG. 8F is a process diagram describing process of manufacturing the optical sensor element and the polycrystalline silicon TFT;

FIG. 8G is a process diagram describing process of manufacturing the optical sensor element and the polycrystalline silicon TFT;

FIG. 8H is a process diagram describing process of manufacturing the optical sensor element and the polycrystalline silicon TFT;

FIG. 8I is a process diagram describing process of manufacturing the optical sensor element and the polycrystalline silicon TFT;

FIG. 8J is a process diagram describing process of manufacturing the optical sensor element and the polycrystalline silicon TFT;

FIG. 8K is a process diagram describing process of manufacturing the optical sensor element and the polycrystalline silicon TFT;

FIG. 8L is a process diagram describing process of manufacturing the optical sensor element and the polycrystalline silicon TFT;

FIG. 8M is a process diagram describing process of manufacturing the optical sensor element and the polycrystalline silicon TFT;

FIG. 8N is a process diagram describing process of manufacturing the optical sensor element and the polycrystalline silicon TFT;

FIG. 8O is a process diagram describing process of manufacturing the optical sensor element and the polycrystalline silicon TFT;

FIG. 8P is a process diagram describing process of manufacturing the optical sensor element and the polycrystalline silicon TFT;

FIG. 8Q is a process diagram describing process of manufacturing the optical sensor element and the polycrystalline silicon TFT;

FIG. 9A is a view showing an embodiment of manufacturing the sensor element which is derived from FIG. 8L and has the structure shown in FIG. 4;

FIG. 9B is a view showing an embodiment of manufacturing the sensor element which is derived from FIG. 8L and has the structure shown in FIG. 4;

FIG. 9C is a view showing an embodiment of manufacturing the sensor element which is derived from FIG. 8L and has the structure shown in FIG. 4;

FIG. 9D is a view showing an embodiment of manufacturing the sensor element which is derived from FIG. 8L and has the structure shown in FIG. 4;

FIG. 9C is a view showing an embodiment of manufacturing the sensor element which is derived from FIG. 8L and has the structure shown in FIG. 4;

FIG. 10A is a cross-sectional view showing a conceptual view for describing another embodiment of an optical sensor element according to the present invention;

FIG. 10B is a top view showing a conceptual view for describing another embodiment of the optical sensor element according to present invention;

FIG. 11A is a process diagram describing process of manufacturing the optical sensor element and the polycrystalline silicon TFT in the case where the optical sensor element described in FIG. 10 is adopted;

FIG. 11B is a process diagram describing process of manufacturing the optical sensor element and the polycrystalline silicon TFT in the case where the optical sensor element described in FIG. 10 is adopted;

FIG. 11C is a process diagram describing process of manufacturing the optical sensor element and the polycrystalline silicon TFT in the case where the optical sensor element described in FIG. 10 is adopted;

FIG. 11D is a process diagram describing process of manufacturing the optical sensor element and the polycrystalline silicon TFT in the case where the optical sensor element described in FIG. 10 is adopted;

FIG. 11E is a process diagram describing process of manufacturing the optical sensor element and the polycrystalline silicon TFT in the case where the optical sensor element described in FIG. 10 is adopted;

FIG. 11F is a process diagram describing process of manufacturing the optical sensor element and the polycrystalline silicon TFT in the case where the optical sensor element described in FIG. 10 is adopted;

FIG. 12 is a view showing an embodiment of a sensor array occupying a certain area, a so-called area sensor, obtained by applying manufacturing steps of FIG. 8, FIG. 9 or FIG. 11;

FIG. 13A is a cross-sectional view of the sensor array of a finger vein authentication device obtained by applying the present invention;

FIG. 13B is a plan view of the sensor array of the finger vein authentication device obtained by applying the present invention;

FIG. 14 is a view showing an embodiment of an image display device with an optical sensor function obtained by applying the manufacturing steps of FIG. 8, FIG. 9, or FIG. 11; and

FIG. 15 is a view showing another embodiment of an image display device with an optical sensor function obtained by applying the manufacturing steps of FIG. 8, FIG. 9, or FIG. 11.

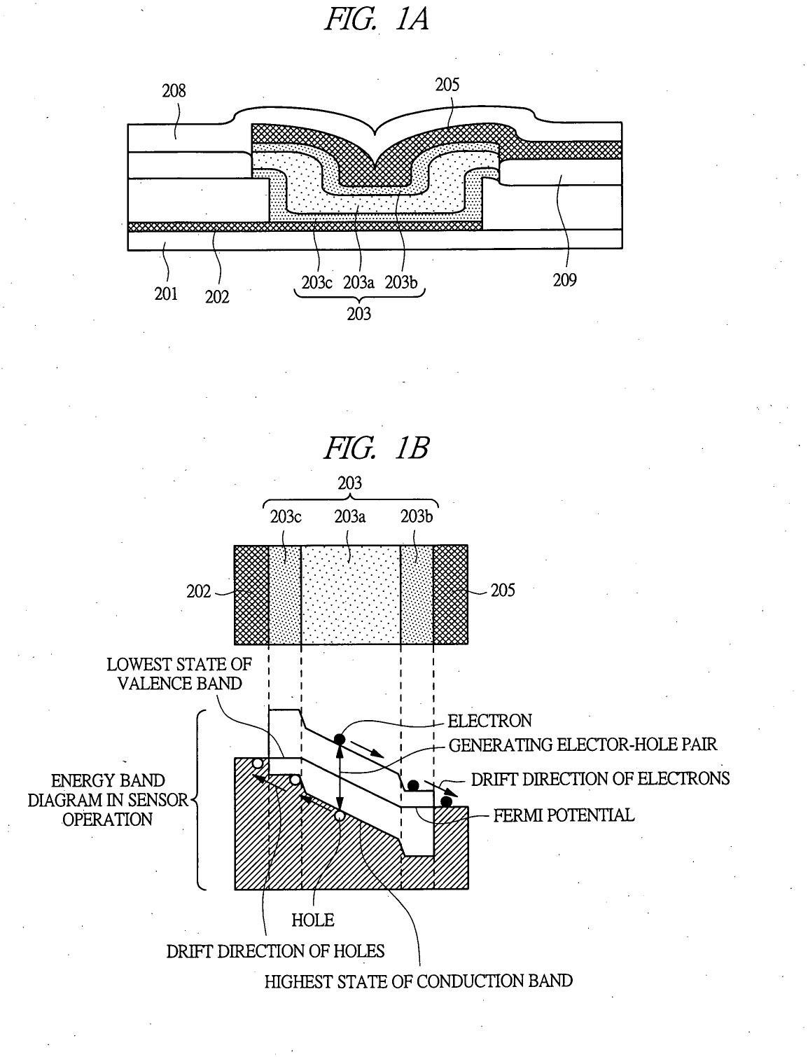

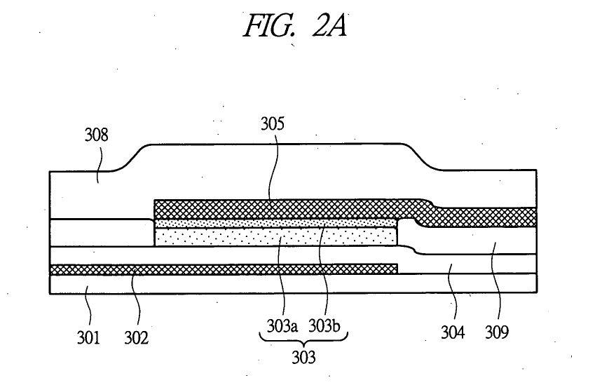

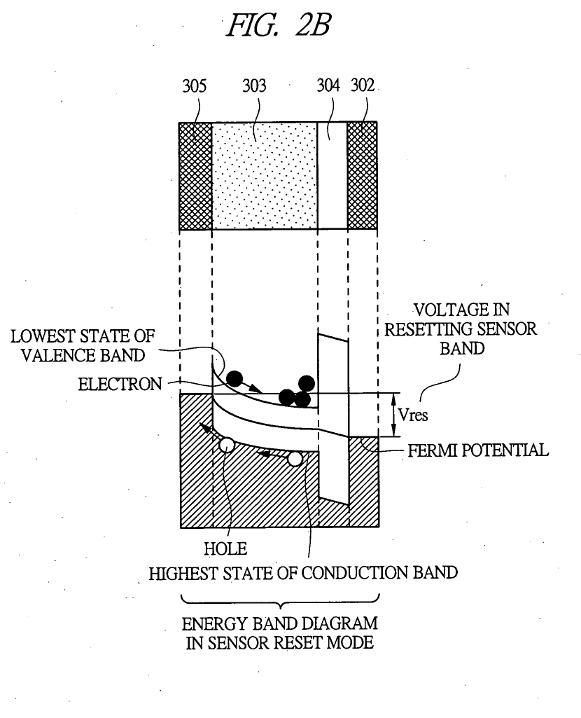

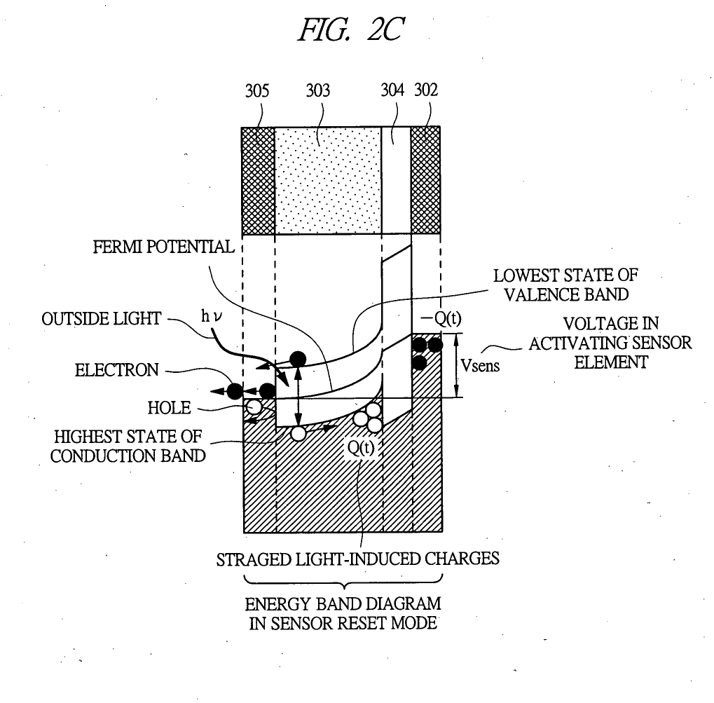

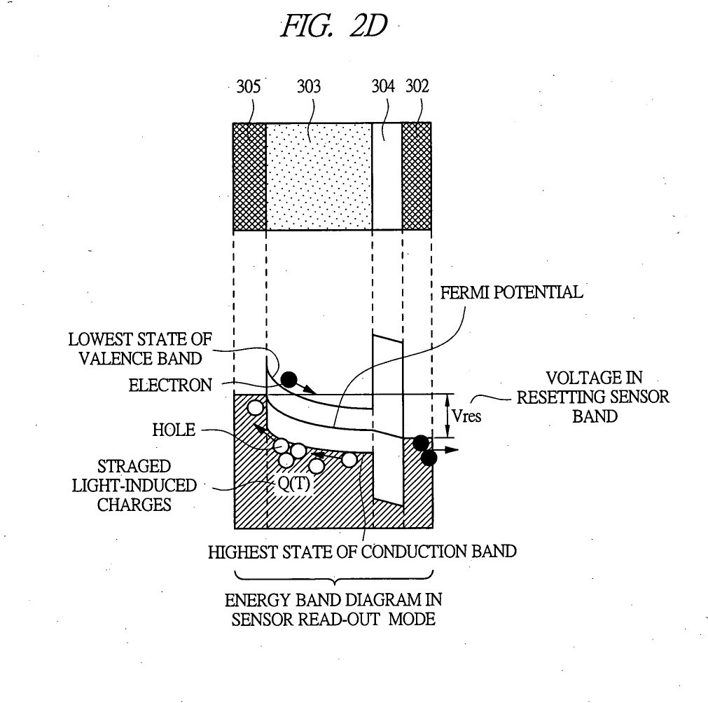

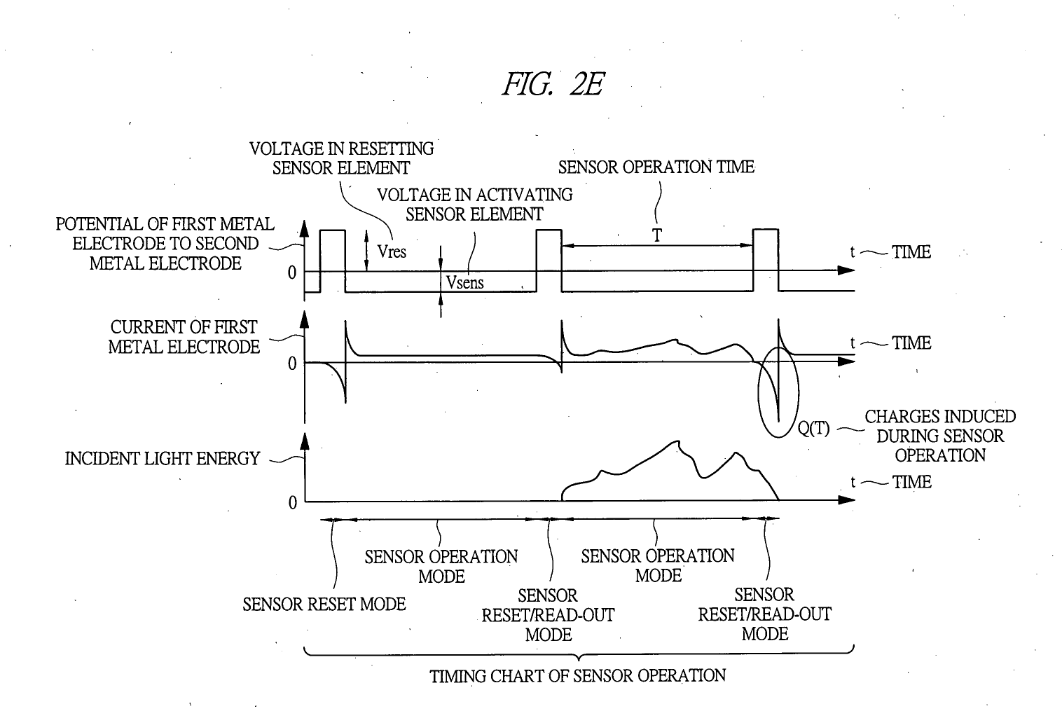

### DESCRIPTIONS OF THE PREFERRED EMBODIMENTS

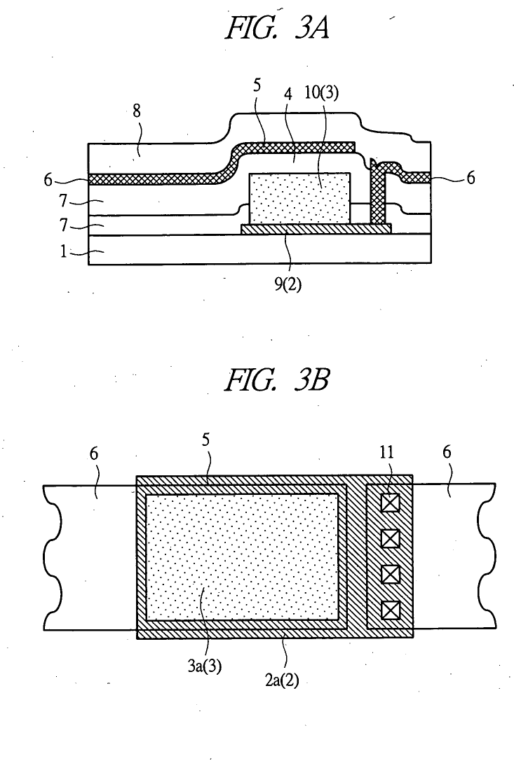

FIGS. 3A and 3B are conceptual diagrams of an optical sensor element according to the present invention. FIG. 3A is a cross-sectional view of the optical sensor element formed on an insulating substrate, and FIG. 3B is a top view thereof.

In FIG. 3A, a first electrode 2 composed of a polycrystalline silicon film 9 is formed on the insulating substrate 1, a photoelectric conversion layer 3 composed of an amorphous silicon film 10 is formed on the first electrode 2, and a second electrode (transparent electrode) 5 transparent to visible near-infrared light is further formed over the photoelectric conversion layer 3 through an insulating layer 4 (here, transparence to visible near-infrared light means that transmittance of energy of light in the range of 400 nm to 1000 nm is 75% or larger)

The first electrode 2 is connected to an interconnection (transparent electrode material) 6 via a contact hole 11. Although the example of FIGS. 3A and 3B show a case where the interconnection 6 is made of the same material forming the second electrode 5, different materials may be used. In the above case, like the first electrode 2, the electrode and the interconnection are connected via a contact hole in the case of second electrode 5. The interconnections 6 connected to each of electrodes 2 and 5 are insulated with an insulating layer for isolating conductive layers 7, and are entirely covered with an insulating layer for passivation 8.

From which sides the detected light enters depends on a manner of mounting of a panel. In a case of normal mounting of the panel (with the insulating substrate 1 side downward), detected light enters from the upper side of FIG. 3A. In the case of reverse mounting (with the insulating substrate 1 side upward), the detected light enters from the lower side of FIG. 3A. The incident light transmits through the second electrode 5 and the insulating layer 4, or the first electrode 2, and reaches a photoelectric conversion layer 3. Part of the energy of the light is photoelectrically converted in the photoelectric conversion layer 3 to generate electron-hole pairs. The charge of only the electrons or the holes is detected to obtain an output signal for the sensor. In the case of the reverse mounting, the second electrode 5 is not necessarily required to be transparent, and the reflected light from the second electrode 5 may be used by selecting materials with a high reflectance for improving the sensitivity of the sensor element.

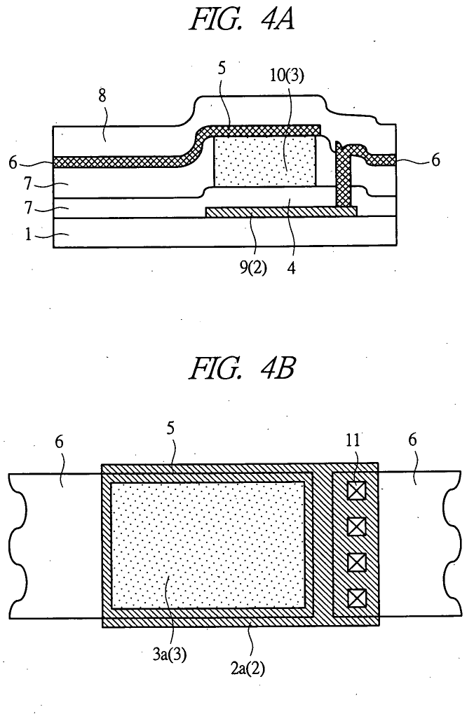

FIGS. 4A and 4B are conceptual diagrams of another optical sensor element according to the present invention. FIG. 4A is a cross-sectional view of the optical sensor element formed on the insulating substrate, and FIG. 4B is a top view thereof.

In FIGS. 4A and 4B, a first electrode 2 composed of a polycrystalline silicon film 9 is formed on an insulating substrate 1, a photoelectric conversion layer 3 composed of an amorphous silicon film 10 is formed over the first electrode 2 through an insulating film 4, and a second electrode (transparent electrode) 5 transparent to visible near-infrared light is further formed on the photoelectric conversion layer 3. The first electrode 2 is connected to an interconnection (transparent electrode material) 6 via a contact hole 11. Although the example of FIGS. 4A and 4B shows a case where the interconnect 6 is made of the same material forming the second electrode 5, different materials may be used. In this case, like the first electrode 2, the electrode and the interconnection are connected via a contact hole in a case of the second electrode 5. The interconnections connected to each of electrodes 2 and 5 are insulated with an insulating layer for isolating conductive layers 7, and are entirely covered with an insulating layer for passivation 8.

From which sides the detected light enters depends on the manner of mounting of the panel, like the element of FIGS. 3A and 3B. In the case of normal mounting of the panel (with the insulating substrate 1 side downward), the detected light enters from the upper side of FIG. 4A. In the case of reverse mounting (with the insulating substrate 1 side upward), the detected light enters from the lower side of FIG. 4A. The incident light transmits through the second electrode 5, or the first electrode 2 and the insulating layer 4, and reaches the photoelectric conversion layer 3. Part of the energy of the light is photoelectrically converted in the photoelectric conversion layer 3 to generate electron-hole pairs. The charges of only the holes (electrons may be detected in some cases) are detected to obtain an output signal for the sensor. In the case of the reverse mounting, the second electrode 5 is not necessarily required to be transparent, and reflected light from the second electrode may be used by selecting materials with a high reflectance for improving sensitivity of the sensor element.

The difference between FIGS. 4A and 4B and FIGS. 3A and 3B is that the insulating layer 4 is in contact with the first electrode 2 or the second electrode 5. The optimum structures depend on type of electrode materials of the second electrode, operational conditions, and the like. Therefore, either one of the structures can be selected on a case-by-case basis.

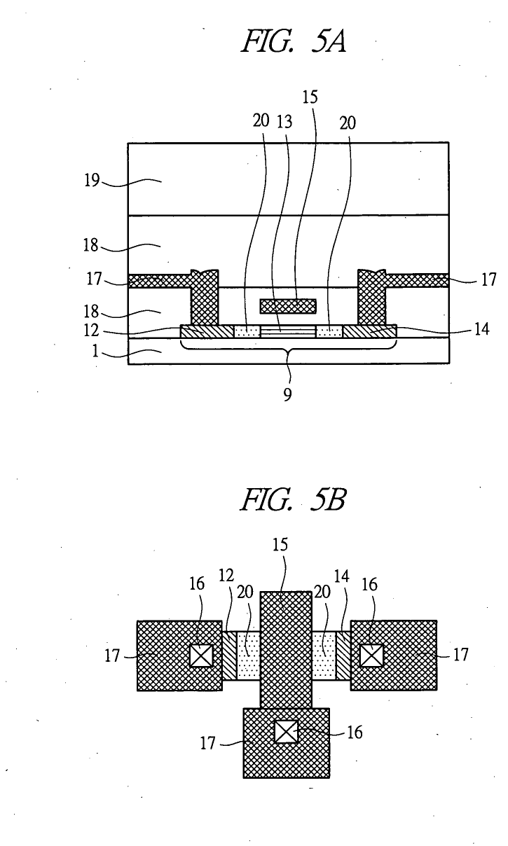

FIGS. 5A and 5B are conceptual diagrams of a thin-film transistor (TFT) widely used as a switch element using a polycrystalline silicon film. FIG. 5A is a cross-sectional view of the TFT formed on an insulating substrate, and FIG. 5B is a top view thereof.

In FIGS. 5A and 5B, a source 12, a channel 13, and a drain 14 of the TFT, which are all made of the same polycrystalline silicon film 9 forming a first electrode 2 of the sensor element, are formed on an insulating substrate 1. A gate electrode 15 made of a conductive film such as a metal film or polycrystalline silicon is formed over these elements 12, 13, and 13 through an insulating film. The source 12, the gate 15, and the drain 14 are connected to interconnections 17 via contact holes 16. The interconnections 17 connected to each electrode are insulated with an insulating layer for isolating conductive layers 18, and are entirely covered with an insulating layer for passivation 19. In the TFT, low concentration impurities implanted layers 20 are provided between the source 11 and the channel 12, and the drain 13 and the channel 12. The purpose of this is to ensure reliability of the element.

The first electrodes 2 of the sensor elements shown in FIGS. 3A and 3B and FIGS. 4A and 4B, and the source 12 and drain 14 of the TFT shown in FIGS. 5A and 5B have to be made to be a conductor by sufficiently reducing resistances thereof by implanting impurities with high concentration. It is desirable that the ideal value is a resistivity of 2.5×10⁻⁴ Ω·m or lower.

The amorphous silicon films 10 in FIGS. 3A and 3B, and FIGS. 4A and 4B are the photoelectric conversion layer 3 of the sensor element. The photoelectric conversion layer 3 is desirably an intrinsic layer to extend lifetime of the generated electron-hole pairs. The ideal value is a resistivity of 1.0×10⁻³ Ω·m or lower.

For preventing the carriers from being injected from the electrode to the photoelectric conversion layer 3, an impurity implanted region with higher concentration 10a, which contacts the electrode, may be provided in the amorphous silicon film 10.

In the sensor element shown in FIGS. 3A and 3B, an impurity with the same kind as that of the impurity implanted into the first electrode 2 are introduced to the region, which contacts the first electrode 2, in the amorphous silicon film 10. FIG. 6 is a cross-sectional view thereof. Here, in FIG. 6, the reference numeral “10a” denotes an impurity implanted region with higher concentration.

In the sensor element shown in FIGS. 4A and 4B, an impurity different in kind from the impurity implanted into the first electrode 2 are introduced to the region, which contacts the second electrode (transparent electrode) 5, in the amorphous silicon film 10. FIG. 7 is a cross-sectional view thereof. Here, in FIG. 7, the reference numeral “10a” denotes an impurity implanted region with higher concentration.

Note that the type of impurities mentioned above represents a donor-type impurity or an acceptor-type impurity on implanting impurities into silicon and activating them. The donor-type impurity includes, for example, phosphorus and arsenic. The acceptor-type impurity includes, for example, boron and aluminum.

The sensor elements of FIGS. 3A and 3B or FIGS. 4A and 4B, and the switch element of FIGS. 5A and 5B are all formed on the same insulating substrate 1 by using a planar process, whereby low cost area sensors integrating sensor driver circuits or image display devices incorporating the optical sensor elements is provided.

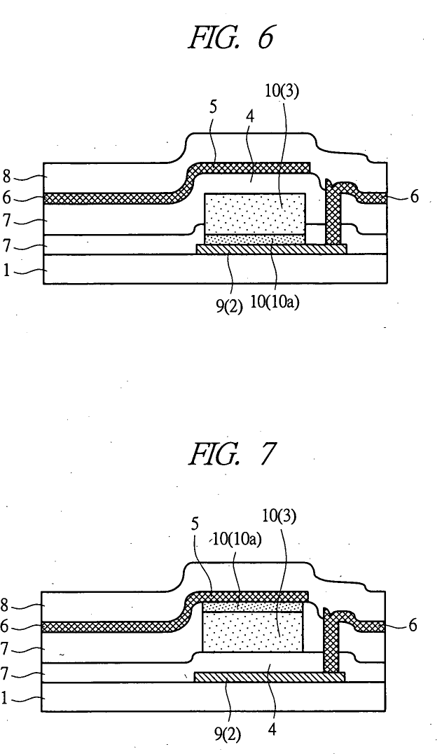

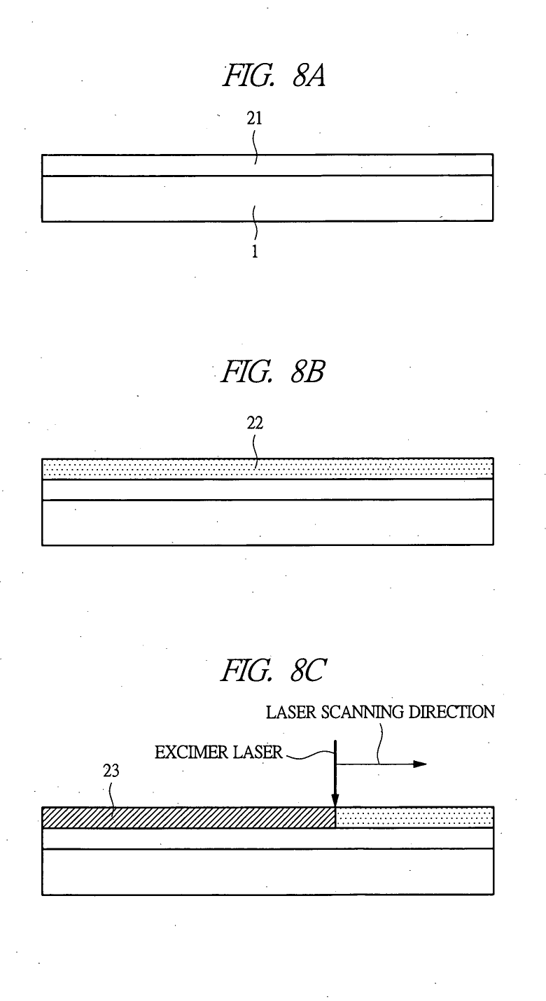

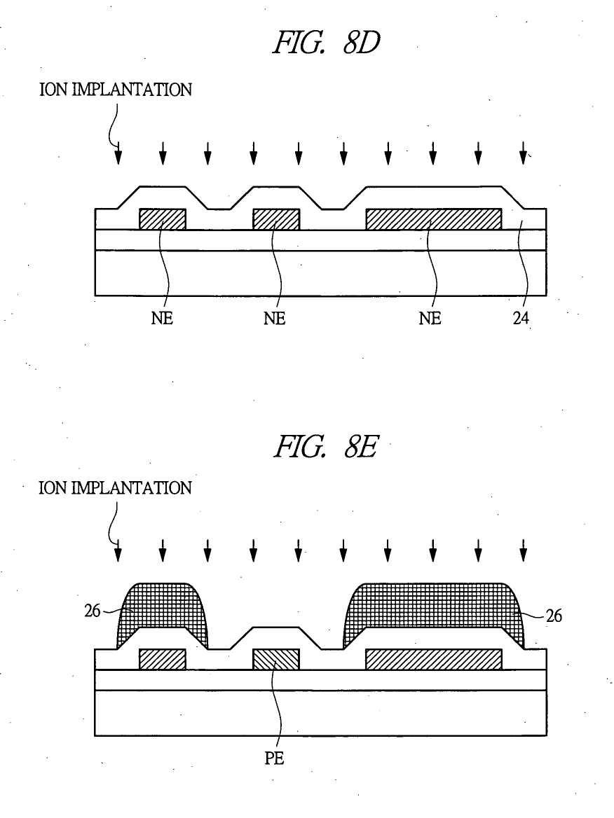

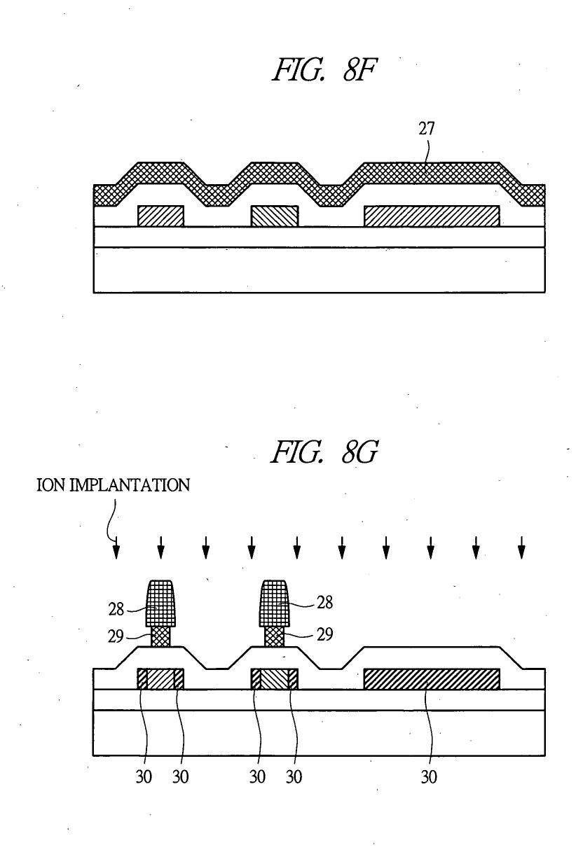

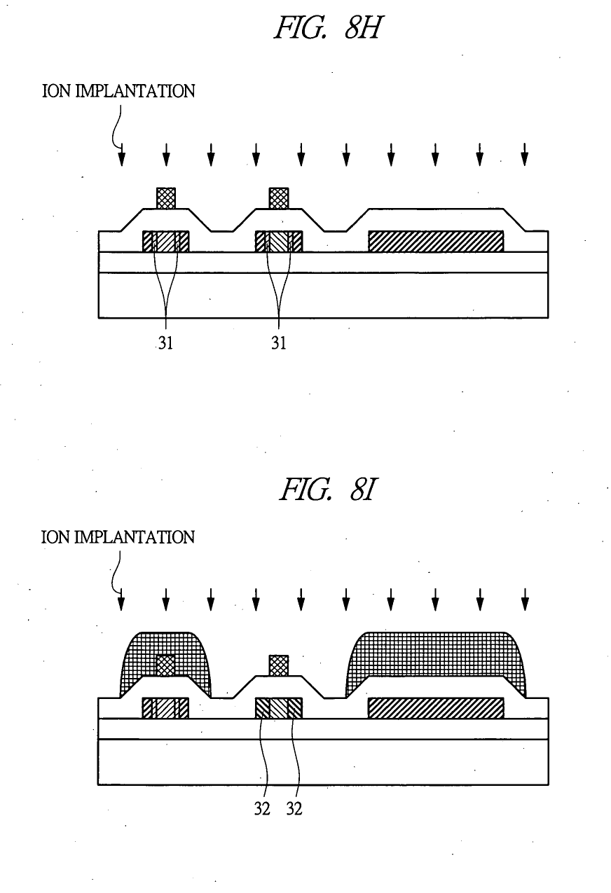

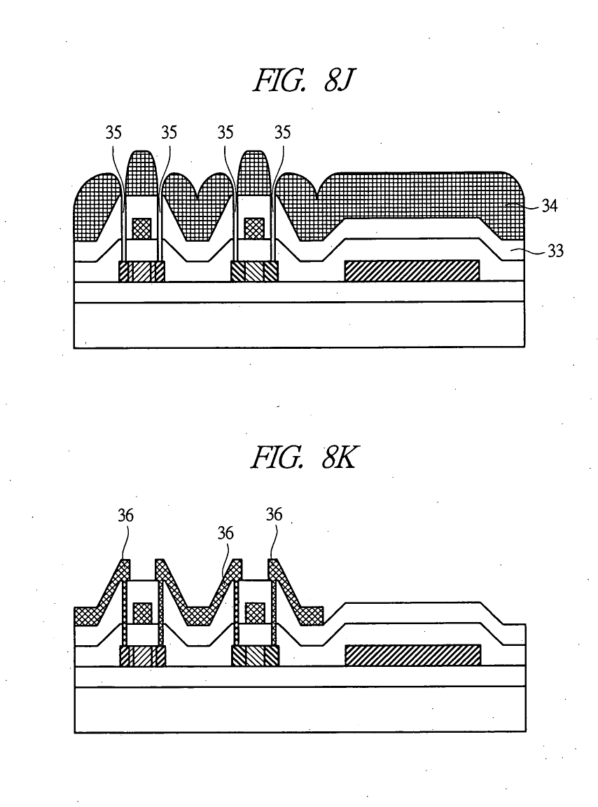

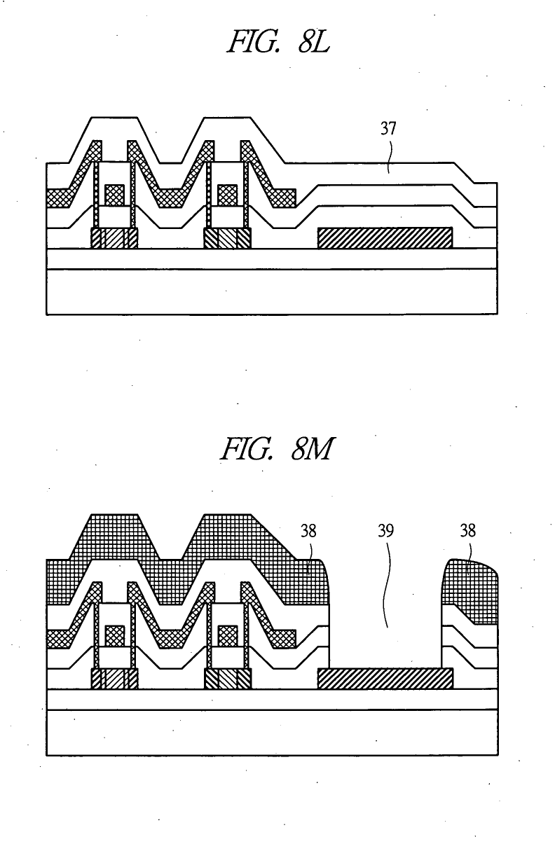

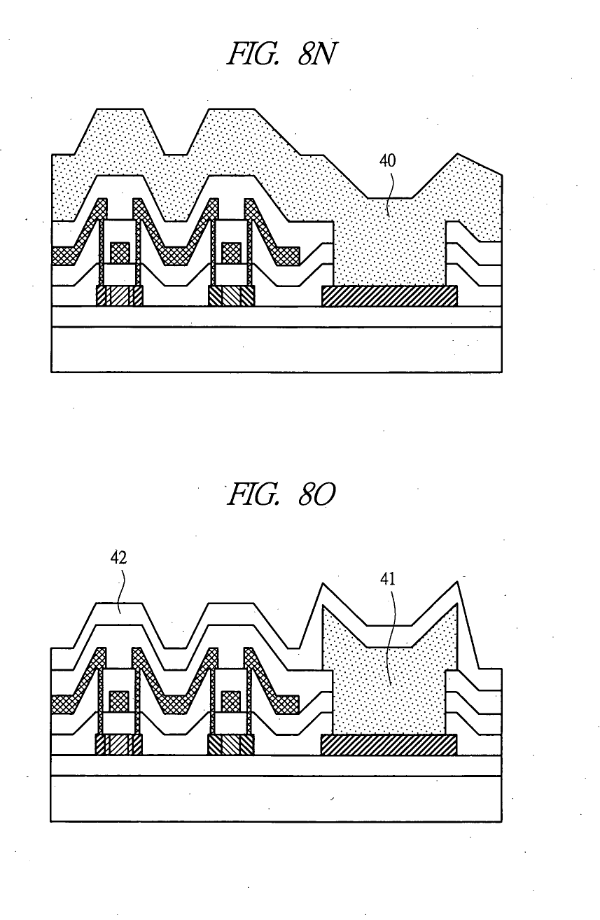

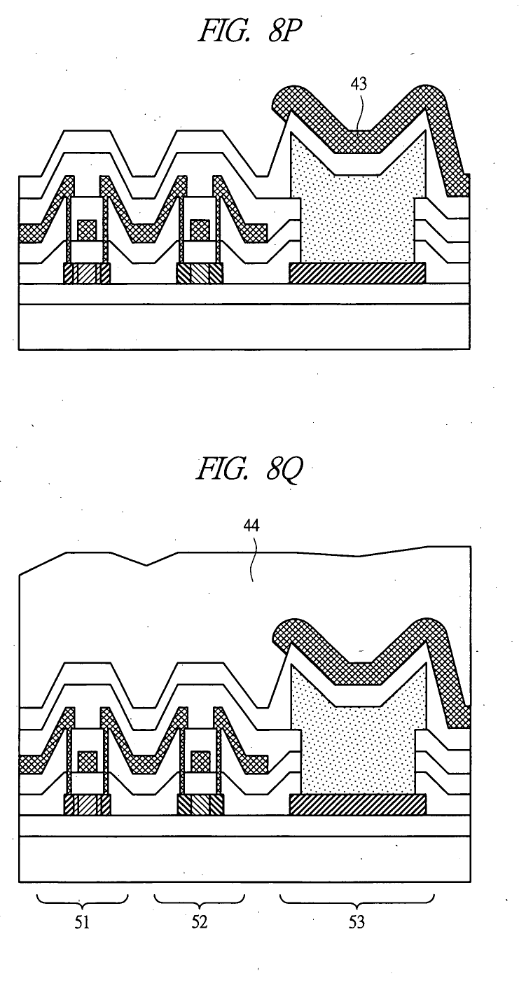

Process of manufacturing the optical sensor element and the polysilicon TFT will be described by using FIGS. 8A to FIG. 8Q. Here, examples up to manufacturing these elements adjoining each other will be described. Only an arrangement of elements is changed according to applications such as an area sensor and a display device, but basic of the process is not changed. The known steps may be added or omitted as necessary. In the present example, the first electrode 2 is assumed to be an N type. If the first electrode is made to be a P type, only covered regions with masks are changed in steps described below.

In FIG. 8A, an insulating substrate 1 is prepared. Here, an inexpensive glass substrate will be exemplified as the insulating substrate 1, but these elements can be formed on a plastic substrate such as PET, an expensive quartz substrate, a metal substrate and the like. In a case of the glass substrate, sodium, boron and other substances are contained in the substrate so that they are to be contaminants to a semiconductor layer. Therefore, an undercoat film 21 such as a silicon oxide film or a silicon nitride film is desirably formed on a surface of the substrate. As shown in FIG. 8B, an amorphous silicon film 22 or a micro-crystalline silicon film 22 is formed on the upper surface by a chemical vapor deposition (CVD) method. Thereafter, as shown in FIG. 8C, Excimer laser is irradiated onto the amorphous silicon film 22 to form a polycrystalline silicon film 23.

Next, in FIG. 8D, the polycrystalline silicon film 23 is processed to form island-like shape polycrystalline silicon films in the photolithography step. Then a gate insulating film 24 composed of a silicon oxide film is formed by CVD. A material of the gate insulating film 24 is not limited to the silicon oxide film, but a material is desirably selected from materials satisfying a high dielectric constant, high insulating property, low fixed charges, interface trapped charges/interface state density, and process consistency. Boron is introduced into the entire island-like shape polycrystalline silicon films through the gate insulating film 24 by an ion-implantation method to form a threshold voltage adjustment layer (boron implanted region with extremely lower concentration) NE of N type TFT.

Furthermore, as shown in FIG. 8E, among an N type TFT region, an N type electrode region, and a P type TFT region, the N type TFT region and the N type electrode region are determined as non-implanted regions with photoresist 26 in the photolithography step. Then, phosphorus is introduced by an ion-implantation method to form a threshold voltage adjustment layer (phosphorus implanted region with extremely lower concentration) PE of the P type TFT. The impurities of the threshold voltage adjustment layer (boron implanted region with extremely lower concentration) NE of the N type TFT and the threshold voltage adjustment layer (phosphorous implanted region with extremely lower concentration) PE of the P type TFT are introduced in order to adjust the threshold voltage of the TFT. As the does amount on the ion-implanting, optimum does between 1×10¹¹ cm⁻² and 1×10¹³ cm⁻² is introduced. In this case, the concentration of major carriers in the boron implanted region with extremely lower concentration and in the phosphorus implanted region with extremely lower concentration are known to be from 1×10¹⁵ to 1×10¹⁷/cm³. Optimum value of the boron implanted amount is determined by the threshold voltage of the N type TFT, and optimum value of the phosphorus implanted amount is determined by the threshold voltage of the P type TFT.

Next, as shown in FIG. 8F, a metal film 27 for the gate electrode is formed by CVD or sputtering. The metal film 27 for the gate electrode is not necessarily required to be a metal film, but, for example, a polycrystalline silicon film with low resistance made by introducing high concentration impurities may be used.

As shown in FIG. 8G, the metal film 27 for the gate electrode is processed in the photolithography step to form the gate electrode 29. Then, phosphorus is introduced by an ion-implantation method using the same photoresist 28 to form an N+ layer (phosphorus implanted region with higher concentration) 30. Since resistance of the electrode must be sufficiently reduced, the dose amount of the phosphorus on the ion-implanting is desirably larger than or equal to 1×10¹⁵ cm⁻². In this case, the concentration of major carriers in the phosphorus implanted region with higher concentration is 1×10¹⁹/cm³ or larger.

After removing the resist shown in FIG. 8G, as shown in FIG. 8H, phosphorus is introduced into both sides of the gate electrode 29 by an ion-implantation method using the gate electrode 29 as a mask in order to form an N− layer (phosphorus implanted region with medium concentration) 31. The introduction of impurity is to improve reliability of the N type TFT. As the dose amount on the ion-implanting, optimum does is between the dose amount of the boron implanted region with lower concentration NE and the phosphorus implanted region with higher concentration N+, that is, the optimum dose of between 1×10¹¹ cm⁻² and 1×10¹⁵ cm⁻² is introduced. In this case, the concentration of major carriers in the N− layer (phosphorus implanted region with medium concentration) 31 is between 1×10¹⁵ and 1×10¹⁹/cm³.

In the present embodiment, a processing difference between the photoresist 28 and the gate electrode 29 is used in the formation of the N− layer (phosphorus implanted region with medium concentration) 31. An advantage of using the processing difference is that photomasks and photolithography steps can be omitted, and the region of the N− layer (phosphorus implanted region with medium concentration) 31 can be uniquely determined with respect to the gate electrode 31. However, a disadvantage is that if the processing difference is small, the N− layer 31 cannot be sufficiently ensured. When the processing difference is small, photolithography steps may be newly added in order to define the N− layer 31.

Next, as shown in FIG. 8I, after determining non-implanted regions of the N type TFT region and N type electrode region with photoresist, boron is introduced into the P type TFT region by an ion-implantation method to form a P+ layer (boron implanted region with higher concentration) 32. Since the resistance of the electrode must be sufficiently reduced, the dose amount on the ion-implanting is desirably 1×10¹⁵ cm⁻² or larger. At this time, the concentration of major carriers in the P+ layer 32 is 1×10¹⁹/cm³ or larger. The electrodes of the TFT and optical sensor element are formed through the above steps.

Note that, in the embodiment, the same amount of boron as that of boron in the threshold voltage adjustment layer (boron implanted region with lower concentration) NE of the N type TFT is also introduced into the threshold voltage adjustment layer (phosphorus implanted region with lower concentration) PE of the P type TFT. The same amount of phosphorus as the total amount of phosphorus in the N− layer (phosphorus implanted region with medium concentration) 31 and N+ layer (phosphorus implanted region with higher concentration) 32 is also introduced into the P+ layer (boron implanted region of higher concentration) 32. However, essentially, these impurities are not needed to be introduced, so that the amount of phosphorus or boron for canceling the different type implanted impurities must be introduced into each layer in order to maintain the type of major carries in the electrodes of the TFT and the optical sensor element. In the embodiment, although there is an advantage that the photolithography step can be simplified and the number of photomasks can be reduced, there is a disadvantage that numerous faults are generated in an active layer of the P type TFT. If characteristics of the P type TFT cannot be ensured, the numbers of photomasks and photolithography steps are increased so that the threshold voltage adjustment layer PE and P+ layer 32 of the P type TFT are covered for preventing unnecessary impurities being introduced.

Next, as shown in FIG. 8J, after forming an insulating layer for isolating conductive layers 33 on the upper part of the gate electrode by CVD using TEOS (tetraethoxysilane) gas as a material, activation annealing of the introduced impurities is performed. Contact holes 35 are formed at the source and drain portions in the photolithography step using the photoresist 34. The insulating layer for isolating conductive layers 33 is to insulate interconnections 36 formed later from the gate electrode 29 and a polycrystalline semiconductor layer that are the lower layers. As the insulating layer 36, any films may be used as long as it has insulating property. However, since parasitic capacity must be reduced, a film having such process consistency as a low relative dielectric constant and small membrane stress is desired when its film thickness is increased. Furthermore, when a display function is required together simultaneously, transparency of the film is important, and thus materials with a high transmittance with respect to a visible light region are desired. In the embodiment, a silicon oxide film made from the TEOS gas as a material is exemplified.

Next, as shown in FIG. 8K, an interconnection 36 is formed in the photolithography step after the formation of a film with material for interconnections. Furthermore, as shown in FIG. 8L, the insulating layer for passivation 37 is formed by CVD. If necessary, additional annealing is performed to improve the TFT characteristics after forming the insulating layer for passivation 37. A material of the film 37 may be any materials as long as it has insulating property like the insulating layer for isolating conductive layers 33 shown in FIG. 8J.

Next, as shown in FIG. 8M, a contact hole 39 is formed in the insulating layer for passivation 37, insulating layer for isolating conductive layers 33, and gate insulting film 24 that are all the upper layers of the first electrode of the sensor element in the photolithography step using the photoresist 38. In the embodiment, an example of manufacturing the sensor element of FIGS. 3A and 3B is described.

Next, as shown in FIG. 8N, an amorphous silicon film 40 is formed by CVD. In this step, in order to reduce the energy level of the interface between the polycrystalline silicon electrode and the amorphous silicon film 40, a surface modification treatment or a cleaning treatment to the polycrystalline silicon electrode is preferably added. The treatment includes hydrofluoric acid cleaning, but any methods may be used. The film forming condition in which hydrogen content in the amorphous silicon film 40 becomes larger than or equal to about 10 atm % is desirable. A great number of non-bound bonds exist in the amorphous silicon, which become recombination centers for the electron-hole pairs generated by light irradiation. The hydrogen in the amorphous silicon film 40 has effects of passivating and inactivating the non-bound bonds. Note that, the introduction of hydrogen after forming the film causes the deterioration of the sensor performance because sufficient amount of hydrogen cannot be introduced into the amorphous silicon film. The amorphous silicon film 40 is basically an intrinsic layer in which impurities are not introduced. However, when the element having the structure shown in FIG. 6 is employed, impurities are mixed to the material gas at the time of starting the formation of a film, whereby an impurity implanted layer with high concentration existing in a region, which is adjacent to the first electrode, in the amorphous silicon layer is formed. By doing this, the leakage is reduced when the irradiation of light does not occur.

Next, as shown in FIG. 8O, the amorphous silicon film 40 is processed in the photolithography step using the photoresist in order to form a island-like shape sensor photoelectric conversion part 41 (amorphous silicon film), and then the insulating film 42 is formed. The insulating film 42 desirably has high coverage to the island-like shape amorphous silicon. The capacity is adjusted by selecting a film having a high dielectric constant or controlling the film thickness.

Next, as shown in FIG. 8P, a second electrode 43 composed of a transparent material is formed in the photolithography step. Any materials may be used as long as they are an electrical conductor transparent to the visible near-infrared light. For example, oxide of ITO, ZnO, or InSb may be used.

Finally, as shown in FIG. 8Q, an insulating layer for passivation 44 is formed. The insulating layer for passivation 44 is particularly to prevent water from entering each element from the outside. Therefore, material having inferior water vapor permeability such as silicon nitride is desired to be employed rather than a silicon oxide film with excellent water vapor permeability.

In the present process, the number of the interconnect layers can be increased as necessary to make a multi-layer by repeating the photolithography steps.

In FIG. 8Q, the N-type TFT 51, the P-type TFT 52, and the sensor element 53 (structure described in FIGS. 3A and 3B) are formed in order from the left.

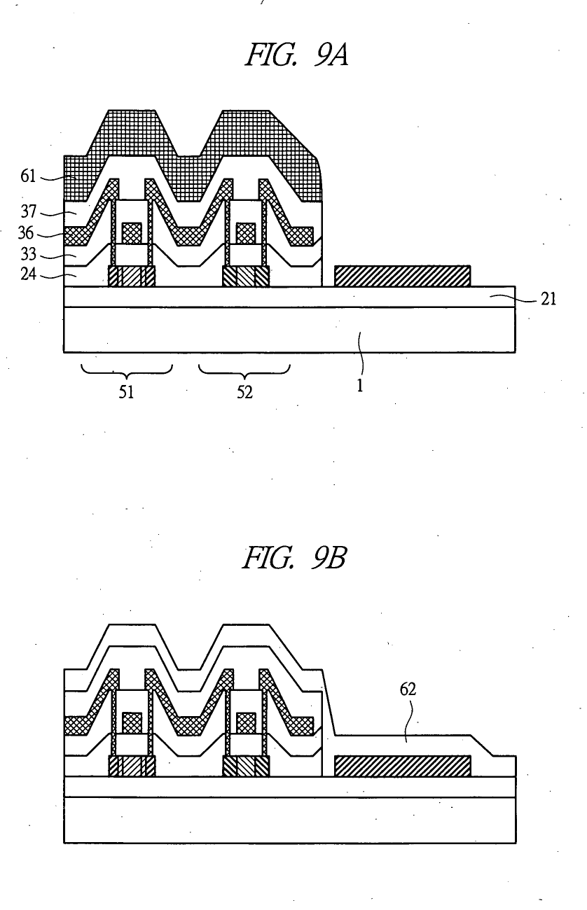

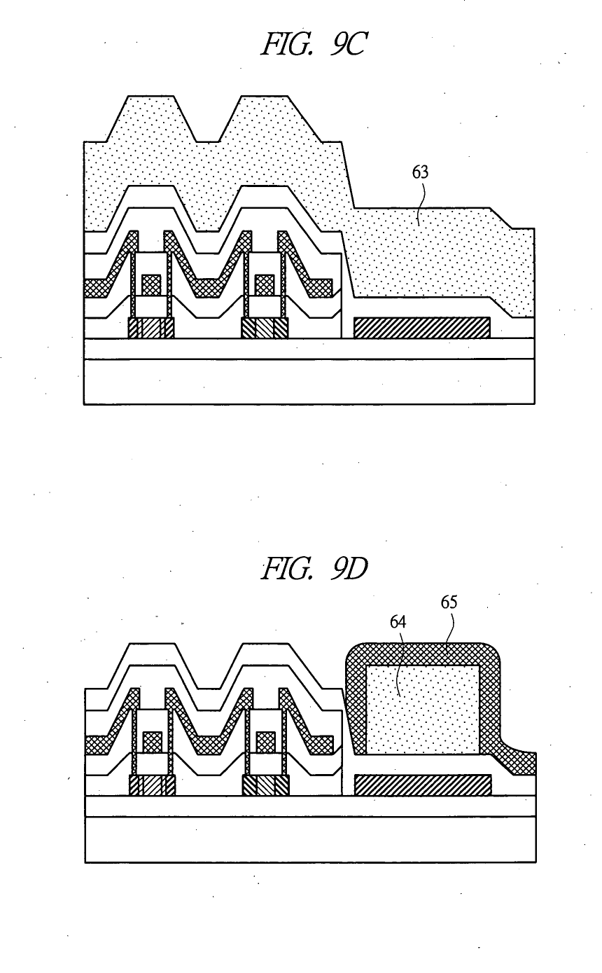

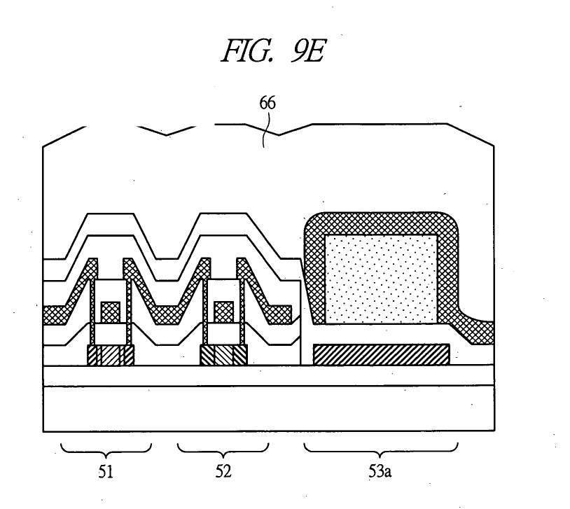

FIGS. 9A to FIG. 9E show a manufacturing example of a sensor element derived from FIG. 8L and having the structure shown in FIGS. 4A and 4B.

As shown in FIG. 9A, the insulating layer for passivation 37, the insulating layer for isolating conductive layers 33, and the gate insulating film 33 that are all the upper layers of the first electrode 2 of the sensor element are removed in the photolithography step using the photoresist 61.

Next, as shown in FIG. 9B, an insulating film 62 is formed by CVD. Here, the insulating film 62 directly on the first electrode of the sensor element is newly formed, but may be prepared in a method that an insulating film with a desired film thickness is left when other insulating film is removed in the previous step.

Next, as shown in FIG. 9C, an amorphous silicon film 63 is formed by CVD. The amorphous silicon film 63 is basically an intrinsic film in which impurities are not introduced. However, when the element having the structure shown in FIG. 7 is employed, impurities are mixed to the material gas immediately before the completion of the formation of a film, whereby an impurity introduced layer with high concentration adjacent to the second electrode 5 in a region of the amorphous silicon layer is formed. By doing this, the leakage is reduced when the irradiation of light does not occur.

As shown in FIG. 9D, after processing the amorphous silicon layer into an island-like shape, a second electrode 65 composed of a transparent material is formed in the photolithography step. Here, in FIG. 9D, the reference numeral “64” denotes a sensor photoelectric conversion part. In FIG. 9D, the second electrode 65 is formed so as to surround the island-like shape amorphous silicon, but may be formed only on the upper part thereof. Finally, as shown in FIG. 9E, an insulating layer for passivation 66 is formed. In the present steps, the number of the interconnection layers can be increased as necessary to make a multi-layer by repeating the photolithography steps.

In FIG. 9E, the N-type TFT 51, the P-type TFT 52, and the sensor element 53a (structure described in FIGS. 4A and 4B) are formed in order from the left.

Although output characteristics is inferior to the sensor elements having the structures shown in FIG. 3 and FIG. 4, an element structure according to the present invention that exhibits better characteristics as compared to the conventional elements and decreases added steps as much as possible in the TFT manufacturing process will be described.

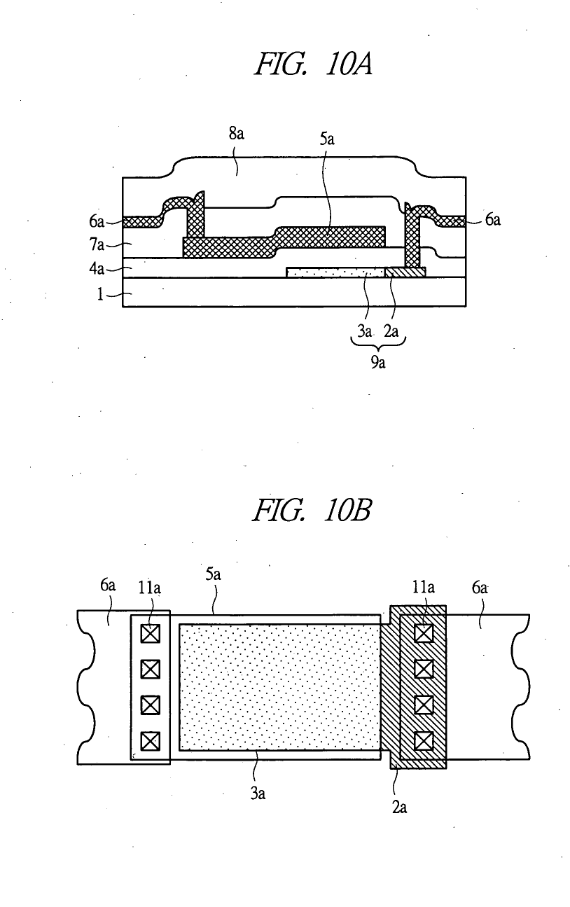

FIG. 10 are conceptual diagrams of another optical sensor element according to the present invention. FIG. 10A is a cross-sectional view of an optical sensor element formed on an insulating substrate, and FIG. 10B is a top view thereof.

In FIG. 10, a first electrode 2a and a photoelectric conversion layer 3a both composed of a polycrystalline silicon film 9a are formed on an insulting substrate 1. Then a second electrode 5a is formed over the upper part of the photoelectric conversion layer 3a through an insulating layer 4a. Each of the first electrode 2a and the second electrode 5a is connected to an interconnection 6a via a contact hole 11a. The example of FIG. 10 show the case where the material of the interconnection 6a is different from the material of the second electrode 5a, but the same material may be used.

The interconnections connected to each of electrodes 2a and 5a are insulated with an insulating layer for isolating conductive layers 7a, and the entire interconnection is covered with an insulating layer for passivation 8a.

The element of FIG. 10 is similar to the elements of FIG. 3 and FIG. 4 in terms in which the photoelectric conversion layer 3a composed of a semiconductor layer and insulating layer 4a are formed between the first electrode 2a and the second electrode 5a, and also the operation methods are the same method.

The features of the invention of FIG. 10 are that the formation of an amorphous silicon film is unnecessary, and that the insulating film 4a and the second electrode 5a of the sensor element are composed of the same material forming the gate insulating film and the gate 15 of the TFT described in FIG. 5. Therefore, the number of added steps can be reduced as much as possible in the TFT manufacturing step to form the switch element (TFT) and the sensor element on the insulating substrate 1.

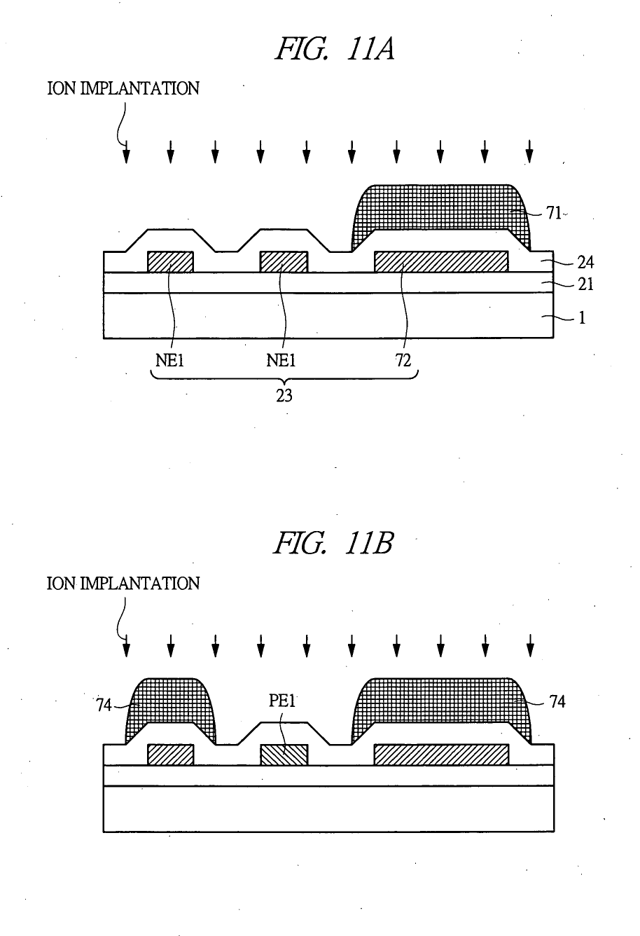

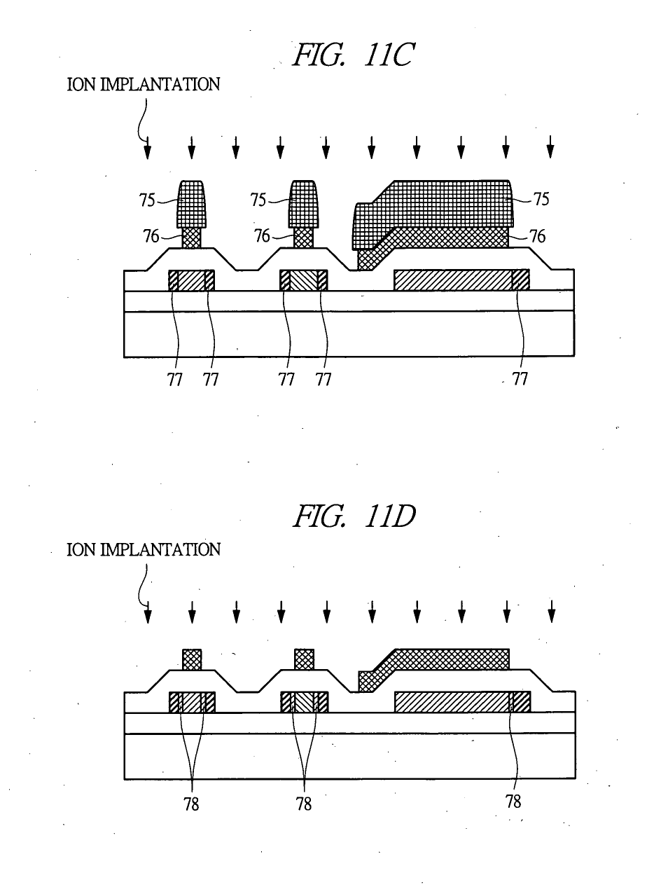

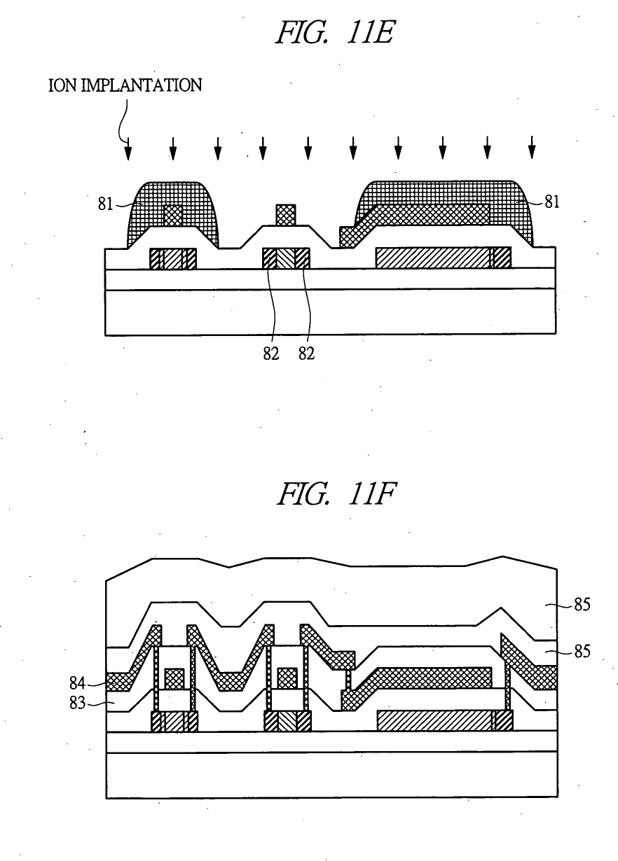

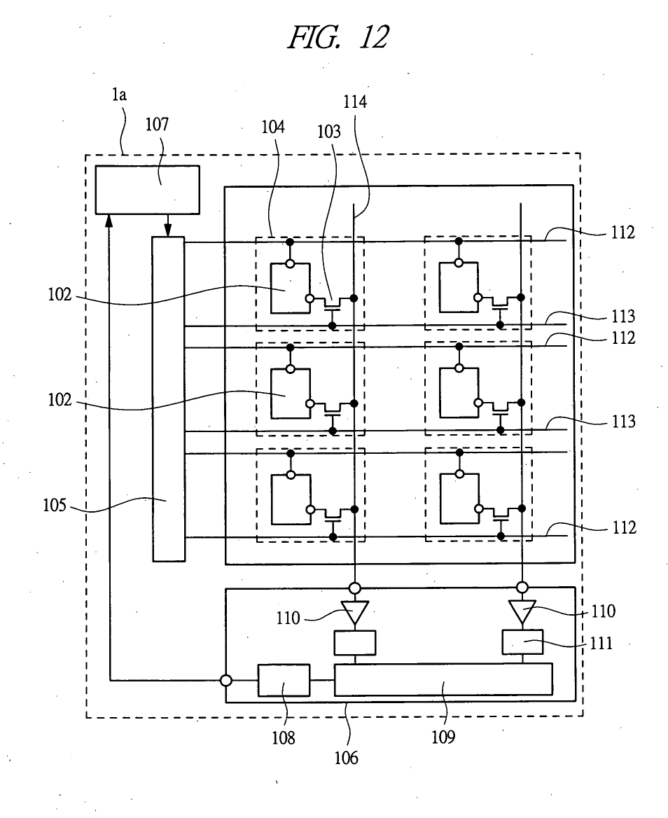

In the case where the optical sensor element described in FIG. 10 is employed, the manufacturing process of an optical sensor element and polycrystalline silicon TFT will be described by using FIGS. 11A to FIG. 11F. Here, an example up to manufacturing these elements adjoining each other will be shown. Only an arrangement of elements is changed according to applications such as an area sensor and a display device, but the basic of the process is not changed. The known steps may be added or omitted as necessary. Here, the first electrode is assumed to be an N type. If the first electrode is made to be a P type, only covered regions with masks are changed in the steps described below.

The steps from processing the polycrystalline silicon film into island-like shape polycrystalline silicon films in the photolithography step up to forming the gate insulating film 24 composed of a silicon oxide film by CVD are common steps of FIG. 8.

As shown in FIG. 11A, boron is introduced by an ion-implantation method while the sensor portion is covered with photoresist 71 to form a threshold voltage adjustment layer (boron implanted region with extremely lower concentration) NE1 of N type TFT. When the process is required to be simpler, boron may be introduced to the entire surface without covering with the photoresist, however the performance of the sensor element is deteriorated by doing this. Therefore, either method is selected according to applications. Here, in FIG. 11A, the reference numeral “72” denotes an intrinsic layer, and “23” denotes a polycrystalline silicon film.

Then, as shown in FIG. 11B, among an N type TFT region, an N type electrode region, and a P type TFT region, the N type TFT region and the N type electrode region are determined as non-implanted regions with photoresist 74 in the photolithography step. Then, phosphorus is introduced by an ion-implantation method to form a threshold voltage adjustment layer (phosphorus implanted region with extremely lower concentration) PE1 of P type TFT.

Next, as shown in FIG. 11C, a metal film for the gate electrode is formed by CVD or sputtering, the metal film for the gate electrode is processed in the photolithography step to form the gate electrode 76, and phosphorus is introduced by an ion-implantation method using the same photoresist 75 to form an N+ layer (phosphorus implanted region with higher concentration) 77.

After removing the resist, as shown in FIG. 11D, phosphorus is introduced into both sides of the gate electrode 76 by an ion-implantation method using the gate electrode 76 as a mask in order to form an N− layer (phosphorus implanted region with lower concentration) 78. As described in FIG. 8, the introduction of impurity is to improve the reliability of the N type TFT. In FIG. 11D, an N− layer (phosphorus implanted region with lower concentration) 78 is also formed between the first electrode and photoelectric conversion layer of the sensor element. In order to avoid the formation of such region, a cover of photoresist is required during the ion-implanting. However, since this sensor element sufficiently functions as a sensor element even when the N− region is formed, it is formed in the embodiment. The process is selected depending on the required sensitivity etc.

Next, as shown in FIG. 11E, the N type TFT region and the N type electrode region are determined as non-implanted regions with photoresist 81, and then boron is introduced into the P type TFT region by an ion-implantation method to form a P+ layer (boron implanted region with higher concentration) 82.

Subsequent steps follow conventional TFT manufacturing steps. FIG. 11F is a completion structure. The dose amount of the impurities for the ion-implantation method is the same amount as that of the process in FIG. 8. Here, in FIG. 11F, the reference numeral “83” denotes an insulating layer for isolating conductive layers, “84” denotes an interconnection, and “85” denotes an insulating layer for passivation.

TFT and the manufacturing process of the TFT have been described as a switch element in FIG. 8, FIG. 9, and FIG. 11. However, diode elements, resistor elements, and other elements may be similarly manufactured. Each electronic circuit with a specific function can be configured by combination of these elements.

FIG. 12 is an embodiment of a sensor array occupying a certain area, a so-called area sensor, obtained by applying the manufacturing steps of FIG. 8, FIG. 9 or FIG. 11. Here, in FIG. 12, the reference numeral “1a” denotes an insulating substrate; “102” an optical sensor element (including amplification circuit); “103” a read-out switch; “104” a set of a optical sensor element, an amplification circuit thereof, and a switch group; “105” a sensor drive circuit; “106” a detecting circuit; “107” a processing circuit; “108” an AD converter; “109” an multiplexer; “110” a detection amplifier, “111” a noise cancel circuit; “112” a reset line, “113” a read-out line; and “114” a date line. It is characterized by that sets 104 of an optical sensor element, an amplification circuit thereof, and a switch group are arranged in a matrix shape, and also a sensor driver circuit 105, a detecting circuit 106, and a processing circuit 107 are manufactured around the matrix on an insulating substrate 1a. Some circuits including the processing circuit 107 are not necessarily required to be formed on the insulating substrate 1a, in such case the circuits are configured by a LSI and the LSI chip may be mounted on the insulating substrate 1a. In addition, instead of the set 104 of the optical sensor element, the amplification circuit thereof, and the switch group, only the optical sensor element or a set of the optical sensor element and one of the elements may be possible to be formed. The embodiment of FIG. 12 can be applied as a light detection sensor array for X-ray imaging devices or biometric authentication devices.

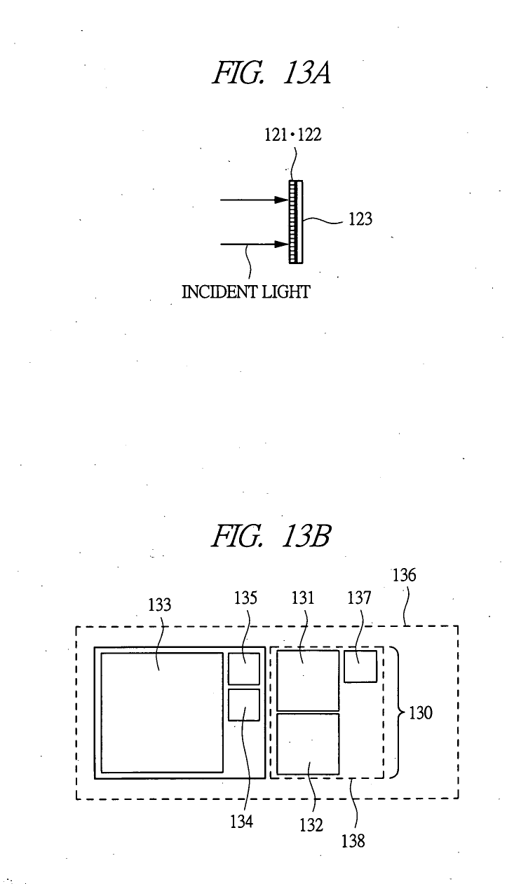

FIG. 13A is a cross-sectional view of a sensor array for finger vein authentication devices. The transmitted/scattered light passing through a finger is collected and separated for each pixel by a micro-lens array 121. Then, the noise components are removed by the color filter 122, and only the near-infrared light as a signal is transmitted and reaches to the reading unit of the area sensor 123 to be converted into an electrical signal. FIG. 13B is a plan view of a finger vein authentication device. Here, in FIG. 13B, the reference numeral “130” denotes processing circuit; “131” an image processing circuit; “132” an camera signal processing circuit; “133” a reading unit; “134” an AD converter; “135” a timing controller; “136” an area sensor; “137” an interface; and “138” a print board. Each configuration circuit is determined whether to be incorporated in the glass substrate or mounted on the print board in view of cost, performance, and the like. In this embodiment, for example, the image processing circuit 131 for processing the electrical signal as image information, and the camera signal processing circuit 132 for controlling the sensor element operation timing and the read-out timing of the sensor unit are mounted on the processing circuit 130.

One example of methods of acquiring area information is described below. The present invention is not limited to the following, and any method may be adopted as long as the detected information in the area can be acquired. The reset signal is transmitted from the sensor driver via the reset line, the sensor is operated for a given time to accumulate the charges induced by light. After being operated for the given time, the sensor switch is opened by the sensor driver through the read-out line to transmit the accumulated charges to the data line as output. The output sent to the data line is amplified, and is converted into digital after the noise is cut in the detecting circuit. This process is sequentially repeated so that the signals for one line is serialized, digitalized, and fed back to the processing circuit at each scan. At the time of completion of the scanning of the entire surface, the information acquisition of light detection for the entire area is completed.

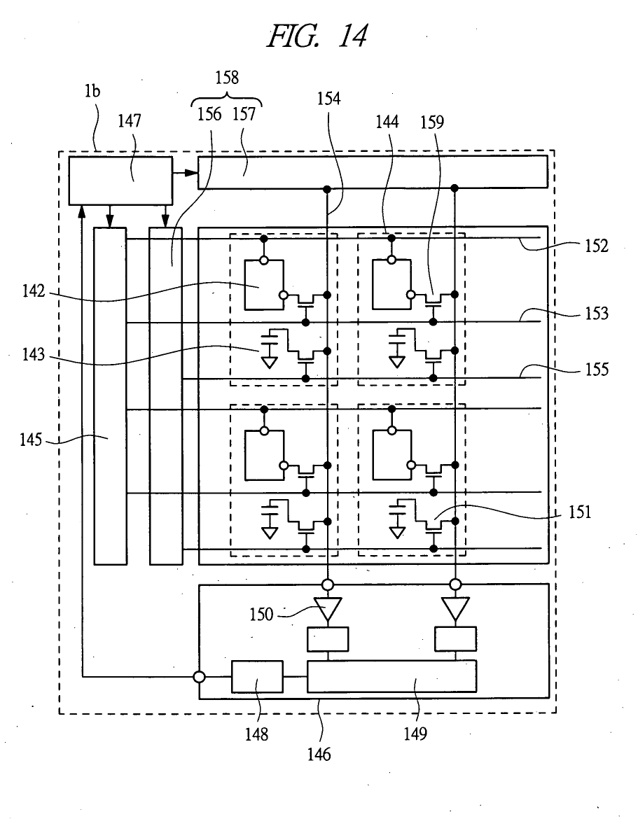

FIG. 14 is an embodiment of an image display device with an optical sensor function obtained by applying manufacturing steps of FIG. 8, FIG. 9, or FIG. 11. Here, in FIG. 14, the reference numeral “1b” an insulate substrate; “142” an optical sensor element (including amplification circuit); “143” a liquid crystal unit; “144” a set of pixels and optical sensor elements (including one sensor element for a plurality of pixels); “145” a sensor driving circuit; “146” a detecting circuit; “147” a processing circuit (LSI); “148” an AD converter; “149” a multiplexer; “150” a detection amplifier; “151” a pixel switch; “152” a reset line; “153” a read-out line; “154” a data line; “155” a gate line; “156” a gate driver; “157” a data driver; “158” a pixel driver circuit; and “159” a sensor switch 159. It is characterized by that sets of one pixel or a plurality of pixels, and optical sensor elements 144 are arranged in a matrix shape, and also a sensor driver circuit 145, a gate driver circuit 156 for image display, a data driver circuit 157, a detecting circuit 146 and a processing circuit 147 are manufactured around the matrix on the insulating substrate 1b. Some circuits including the processing circuit 147 are not necessarily required to be formed on the insulating substrate 1b, in such case, the circuits are configured by a LSI and the LSI chip may be mounted on the insulating substrate 1b. A set of one pixel or a plurality of pixels, and optical sensor elements 144 may include an amplification circuit or a switch group. An embodiment of FIG. 14 can be applied to a display panel with an input function, such as a light pen, a stylus pen, and finger touch.

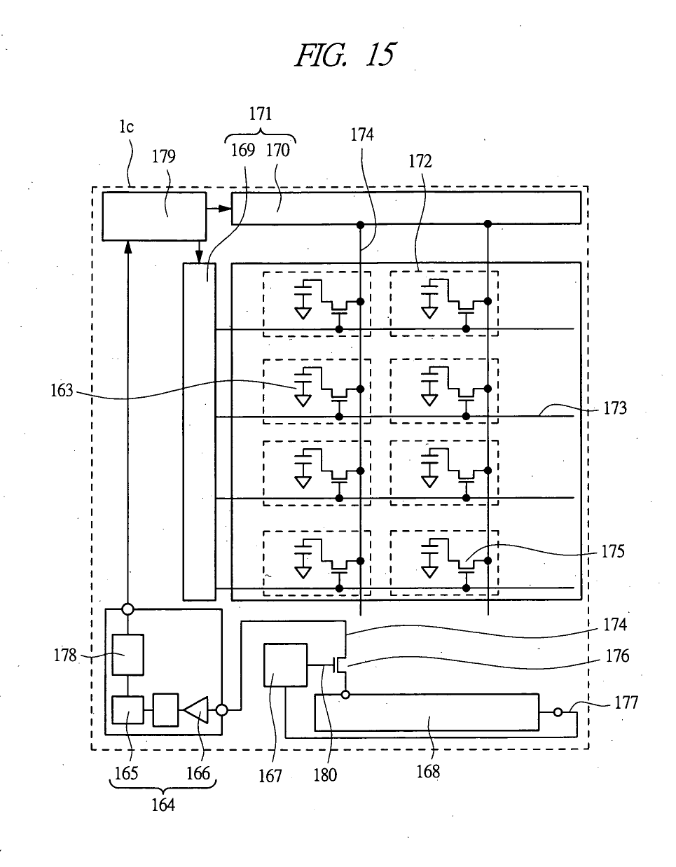

FIG. 15 is an embodiment of an image display device with an optical sensor function obtained by applying the manufacturing steps of FIG. 8, FIG. 9, or FIG. 11. Here, in FIG. 15, the reference numeral “1c” denotes an insulating substrate; “163” a liquid crystal unit; “164” a detecting circuit; “165” a multiplexer; “166” a detection amplifier; “167” a sensor drive circuit; “168” an optical sensor element; “169” a gate driver; “170” a data driver; “171” a pixel driver circuit; “172” a pixel; “173” a gate line; “174” a date line; “175” a pixel switch; “176” a sensor switch; “177” a reset line; “178” an AD converter; “179” a processing circuit (LSI); and “180” a read-out line. Pixels 172 are arranged in a matrix shape, and also an optical sensor element 168, a pixel driver circuit 171 and a sensor driver circuit 167 are disposed around the matrix. In the present embodiment, the sensor is disposed outside a liquid crystal display unit. Some circuits including the processing circuit 179 are not necessarily required to be formed on the insulating substrate 1c, in such case, the circuits are configured by a LSI and the LSI chip may be mounted on the insulating substrate 1c. The embodiment of FIG. 15 can be applied to, for example, a display panel having a light adjustment function.

According to the optical sensor of the present invention, near-infrared light can be detected by the sensor. Furthermore, the amplification circuits that are made up of the switch elements formed with the same film forming the first electrode can be integrated in each sensor element in the sensor array. According to the present invention, thinner and lower-cost biometric authentication devices as compared to conventional products can be provided.

Since the first electrode can be formed with the same film of the polycrystalline silicon film constituting the active layer of the switch element, the structure in which the sensor element is stacked on the upper layer of the circuit (switch element) is avoided, and therefore the optical characteristics can be ensured. Moreover, the number of manufacturing steps can be reduced, and therefore deterioration in yield can be avoided.

What is claimed is:

1. An optical sensor element formed over an insulating substrate, comprising:
a first electrode;
a second electrode;
a photoelectric conversion layer composed of a semiconductor layer formed between the first electrode and the second electrode; and
an insulating film formed between the first electrode and the second electrode,
wherein the first electrode is composed of a polycrystalline silicon film.

2. The optical sensor element according to claim 1,
wherein the photoelectric conversion layer composed of an amorphous silicon film is formed on an upper part of the first electrode, the insulating layer is formed on an upper part of the photoelectric conversion layer, and the second electrode is further formed on an upper part of the insulating layer.

3. The optical sensor element according to claim 2,
wherein the first electrode has a resistivity of 2.5×10⁻⁴ Ω·m or smaller, and the photoelectric conversion layer has a resistivity of 1.0×10⁻³ Ω·m or larger.

4. The optical sensor element according to claim 2,
wherein the second electrode has a transmittance of 75% or larger with respect to light of a visible near-infrared light region of 400 nm to 1000 nm.

5. The optical sensor element according to claim 2,
wherein a region adjacent to an interface with the first electrode in the amorphous silicon film forming the photoelectric conversion layer is an impurity implanted region with higher concentration of 1×10²⁵/m³ or higher.

6. The optical sensor element according to claim 5,
wherein an impurity element with the same kind as that of an impurity element in the impurity implanted region with higher concentration is present in the first electrode, and is at least one selected from phosphorus, arsenic, boron, and aluminum.

7. The optical sensor element according to claim 2,
wherein the insulating layer is composed of a silicon oxide layer or a silicon nitride layer.

8. The optical sensor element according to claim 1,
wherein the insulating layer is formed on an upper part of the first electrode, the photoelectric conversion layer composed of an amorphous silicon film is formed on an upper part of the insulating layer, and the second electrode is further formed on an upper part of the photoelectric conversion layer.

9. The optical sensor element according to claim 8,
wherein the first electrode has a resistivity of 2.5×10⁻⁴ Ω·m or smaller, and the photoelectric conversion layer has a resistivity of 1.0×10⁻³ Ω·m or larger.

10. The optical sensor element according to claim 8,
wherein the second electrode has a transmittance of 75% or larger with respect to light of a visible near-infrared light region of 400 nm to 1000 nm.

11. The optical sensor element according to claim 8,
wherein in the amorphous silicon film forming the photoelectric conversion layer, a region adjacent to an interface with the second electrode is an impurity implanted region with higher concentration of 1×10²⁵/m³ or higher.

12. The optical sensor element according to claim 11,
wherein an impurity element different in kind from an impurity element in the impurity implanted region with higher concentration is present in the first electrode, and is at least one selected from phosphor, arsenic, boron, and aluminum.

13. The optical sensor element according to claim 8,
wherein the insulating layer is composed of a silicon oxide layer or a silicon nitride layer.

14. The optical sensor element according to claim 1,
wherein the first electrode; the photoelectric conversion layer adjacent to the first electrode and composed of the same film of the polycrystalline silicon film forming the first electrode; the insulating layer formed on an upper part of the photoelectric conversion layer; and the second electrode formed on an upper part of the insulating layer are formed.

15. The optical sensor element according to claim 14,
wherein the first electrode has a resistivity of 2.5×10⁻⁴ Ω·m or smaller, and the photoelectric conversion layer has a resistivity of 1.0×10⁻³ Ω·m or larger.

16. The optical sensor element according to claim 14,
wherein the second electrode has a transmittance of 75% or larger with respect to light of a visible near-infrared light region of 400 nm to 1000 nm.

17. The optical sensor element according to claim 14,
wherein the insulating layer is composed of a silicon oxide layer or a silicon nitride layer.

18. An optical sensor device comprising:
an optical sensor element formed on an insulating substrate, wherein the optical sensor element includes a first electrode composed of a polycrystalline silicon film, a second electrode, a photoelectric conversion layer composed of a semiconductor layer formed between the first electrode and the second electrode, and an insulating layer formed between the first electrode and the second electrode; and
at least one of a thin-film transistor device, a diode element, and a resistor element, each of which is composed of the same film of the polycrystalline silicon film forming the first electrode of the optical sensor element and which configure an active layer
wherein an amplification circuit and a sensor driver circuit constituted by at least one of the thin-film transistor device, the diode element, and the resistor element are manufactured on the same insulating substrate together with the optical sensor element.

19. The optical sensor device according to claim 18,
wherein sets of the optical sensor or the optical sensor element and amplification circuit thereof, and a switch group are arranged in a matrix shape, and the sensor driver circuit is disposed around the matrix.

20. An image display device comprising:
An optical sensor device including:
an optical sensor element formed over an insultating film, wherein the optical sensor element includes a first electrode composed of a polycrystalline silicon film, a second electrode, a photoelectric conversion layer composed of a semiconductor layer formed between the first electrode and the second electrode, and an insulating layer formed between the first electrode and the second electrode; and
at least one of a thin-film transistor device, a diode element, and a resistor element, each of which is composed of the same film of the polycrystalline silicon film forming the first electrode of the optical sensor element and which configure an active layer,
wherein an amplification circuit and a sensor driver circuit constituted by at least one of the thin-film transistor device, the diode element, and the resistor element are manufactured on the same insulating substrate together with the optical sensor element,
wherein a pixel switch, an amplification circuit and a pixel driver circuit, each of which is constituted by at least one of the thin-film transistor device, the diode element, and the resistor element, are manufactured on the same insulating substrate.

21. The image display device according to claim 20,
wherein sets of one pixel or a plurality of pixels, the optical sensor element or the optical sensor and the amplification circuit thereof, and a switch group are arranged in a matrix shape, and the pixel driver circuit and the sensor driver circuit are disposed around the matrix.

22. The image display device according to claim 20,
wherein the pixels are arranged in a matrix shape, and the optical sensor element, the pixel driver circuit, and the sensor driver circuit are arranged at a periphery of the matrix.
